(19) United States
(12) Patent Application Publication
(10) Pub. No.: US 2012/0181573 A1
(43) Pub. Date: Jul. 19, 2012

(54) TRANSPARENT CONDUCTIVE OXIDES HAVING A NANOSTRUCTURED SURFACE AND USES THEREOF

(75) Inventors: Arie ZABAN, Shoham (IL); Larissa GRINIS, Rishon LeZion (IL)

(73) Assignee: BAR-ILAN UNIVERSITY, Ramat-Gan (IL)

(21) Appl. No.: 13/432,368

(22) Filed: Mar. 28, 2012

Related U.S. Application Data
(63) Continuation-in-part of application No. 12/513,222, filed on Jun. 3, 2009.
(60) Provisional application No. 60/855,753, filed on Nov. 1, 2006.

(51) Int. Cl. H01L 51/52; H01L 51/44; B32B 3/00

(52) U.S. Cl. 257/99; 428/141; 257/459; 257/E51.019; 257/E51.012

(57) ABSTRACT

The present invention provides a transparent conductive oxide (TCO) having a modified, more specifically, a nanostructured upper surface, and such a TCO when further comprising a layer of a metal or an alloy thereof deposited on said nanostructured upper surface. The latter can be applied in optoelectronic devices such as organic light-emitting diode (OLED) devices; photovoltaic cells such as organic thin film (OPV) solar cells, compound semiconductor thin film solar cells, dye sensitized solar cells (DSSCs); and photochemical water splitting devices.

### CROSS-REFERENCE TO RELATED APPLICATIONS

The present application is a continuation-in-part application of U.S. patent application Ser. No. 12/513,222, which is a 371 national stage application of PCT/IL2007/001298, filed Oct. 25, 2007, and claims the benefit of U.S. Provisional Patent Application No. 60/855,753, filed Nov. 1, 2006, now expired, the entire contents of each and all these applications being herewith incorporated by reference in their entirety as if fully disclosed herein.

### FIELD OF THE INVENTION

The present invention relates to a transparent conductive oxide (TCO) having a modified, more specifically, a nanostructured upper surface, and to such a TCO when further comprising, on said nanostructured upper surface, a metal or an alloy layer.

### ABBREVIATIONS

EPD, electrophoretic deposition; FIB, focused ion beam; FTO, fluorine doped tin oxide; HRSEM, high resolution scanning electronic microscopy; ITO, indium-tin oxide; PEN, polyethylenenaphtalate; PET, polyethylene-terephtalate.

### BACKGROUND OF THE INVENTION

Transparent conductive oxide (TCO)-coated substrates are widely used in optoelectronic devices due to their transparency and electrical conductance. However, the main disadvantages of TCO-coated substrates are associated with the relatively low conductivity of these substrates. In most cases, performance of large area TCO-coated glass- and plastic-based electronic devices, e.g., organic light-emitting diodes (OLEDs) for lighting and displays, and photovoltaic cells, is inferior to small size devices because of the high resistive losses associated with the sheet resistance of the substrates. In order to avoid these resistive losses, metal grid-embedded TCO-coated plastic and glass substrates are required. For these, high conductivity and excellent adhesion of the metallic grid to the TCO are absolutely necessary. Usually, metallic grids are produced from high conductance metals like silver or copper. Nevertheless, in cases wherein corrosive materials are used in the electronic device, more stable to corrosion metals or metal alloys should be applied.

The main problem in the preparation of such metallic grids on TCO is the poor adhesion of both metals and metal alloys to TCO, resulting from the absolutely different chemical and physical properties of metals and oxides. It is known that adhesion of metals to metals is generally much better than adhesion of metals to oxides, and that substrates with a higher roughness have better adhesion to deposited metals.

### SUMMARY OF INVENTION

It has been found, in accordance with the present invention, that nickel-cobalt alloys are highly resistant to corrosion, thus, to iodine-containing redox electrolytes; highly stable at the sintering temperatures for glass-based photoelectrochemical devices (450-550° C.); and have a low recombination rate with electrons in nanoporous semiconductors at operational conditions, a good electrical conductivity and a satisfactory plasticity. These alloys are, thus, suitable as current collectors and conductive interconnects for use in photoelectrochemical applications and, in particular, in dye-sensitized solar cells (DSSCs).

In one aspect, the present invention thus relates to a current collector comprising a nickel-cobalt alloy for use in photochemical applications.

In another aspect, the present invention relates to a conductive interconnect comprising a nickel-cobalt alloy for use in photochemical applications.

In a further aspect, the present invention relates to a transparent conductive oxide (TCO) on which a nickel-cobalt alloy is deposited. In a preferred embodiment, the TCO on which a nickel-cobalt alloy is deposited is an electrode for a photochemical application, preferably a dye-sensitized solar cell (DSSC).

In still a further aspect, the present invention provides a method for electrochemical or chemical deposition of a metal or an alloy on a transparent conductive oxide (TCO) surface, comprising: (i) reduction of the upper layer of the TCO surface; and (ii) electrochemical or electroless deposition of said metal or alloy on the reduced TCO surface. In certain embodiments, this method further comprises an etching of the reduced metal obtained in the reduction step (i) prior to electrochemical or electroless deposition of said metal or metal alloy on the reduced TCO surface.

As found while reducing the present invention to practice, reduction of the upper layer of a TCO surface optionally followed by etching of the metal nanoparticles and/or nano-islands obtained, prior to deposition of a metal or an alloy thereof on said TCO surface, greatly improve the adhesion of said metal or alloy to said TCO surface. In fact, the outcome of such a process is a TCO having a modified surface, more specifically a nanostructured upper surface being characterized by (i) nano-holes, nano-grooves, nano-nets and/or chains of nano-holes; and optionally (ii) nanoparticles and/or nano-islands of a metal reduced from metal ions in the TCO surface, and consequently, substantially increased roughness compared with that of said TCO prior to that process. Furthermore, in cases no etching is performed, the metal nanoparticles and/or nano-islands formed on the TCO upper surface act as deposition centers that initiate and improve the adhesion with the deposited metal or metal alloy.

In still another aspect, the present invention thus relates to a transparent conductive oxide (TCO) comprising a metal oxide either doped with ions of a chemical element or in a slightly reduced form, wherein said TCO has a nanostructured upper surface being characterized by (i) nano-holes, nano-grooves, nano-nets and/or chains of nano-holes; and optionally (ii) nanoparticles and/or nano-islands of a metal reduced from metal ions in said TCO. In a particular such aspect, the invention relates to such a TCO, wherein said nanostructured upper surface obtained by a method comprising reduction of metal ions in the upper layer of a surface of a TCO; and optionally etching of the reduced metal nanoparticles and/or nano-islands obtained.

In yet another aspect, the present invention relates to a transparent conductive oxide (TCO) comprising a metal oxide and having a nanostructured upper surface as defined above, further comprising, on said nanostructured upper surface, a layer of a metal or an alloy thereof.

In a further aspect, the present invention provides an optoelectronic device, e.g., an organic light-emitting diode (OLED) device, comprising a transparent conductive oxide (TCO) comprising a metal oxide and having a nanostructured upper surface as defined above, further comprising, on said nanostructured upper surface, a layer of a metal or an alloy thereof.

In still a further aspect, the present invention provides a photovoltaic cell, e.g., an organic thin film (OPV) solar cell, a compound semiconductor thin film solar cell, or a dye sensitized solar cell (DSSC), comprising a transparent conductive oxide (TCO) comprising a metal oxide and having a nanostructured upper surface as defined above, further comprising, on said nanostructured upper surface, a layer of a metal or an alloy thereof.

In yet a further aspect, the present invention provides a photochemical water splitting device comprising a transparent conductive oxide (TCO) comprising a metal oxide and having a nanostructured upper surface as defined above, further comprising, on said nanostructured upper surface, a layer of a metal or an alloy thereof.

### BRIEF DESCRIPTION OF DRAWINGS

FIGS. 1A-1B show top-view (1A) and 45°-tilted (1B) HRSEM images of FTO-glass 15 Ohm/square (Pilkington, USA) prior to nano-structuring.

FIGS. 2A-2B show top-view (2A) and 45°-tilted (2B) HRSEM images of FTO-glass 15 Ohm/square (Pilkington, USA) after reduction.

FIGS. 3A-3B show top-view (3A) and 45°-tilted (3B) HRSEM image of FTO-glass 15 Ohm/square (Pilkington, USA) after reduction and etching.

FIG. 4 shows FIB image of a cross-section of FTO-glass 15 Ohm/square (Pilkington, USA) prior to nano-structuring.

FIG. 5 shows FIB image of a cross-section of FTO-glass 15 Ohm/square (Pilkington, USA) after reduction and etching.

FIG. 6 shows top-view HRSEM image of FTO-glass 8 Ohm/square (Pilkington, USA) prior to nano-structuring.

FIG. 7 shows top-view HRSEM image of FTO-glass 8 Ohm/square (Pilkington, USA) after reduction.

FIG. 8 shows top-view HRSEM image of FTO-glass 8 Ohm/square (Pilkington, USA) after reduction and etching.

FIG. 9 shows top-view HRSEM image of FTO-glass 8 Ohm/square (Pilkington, USA) after reduction stronger than that shown in FIG. 7.

FIG. 10 shows top-view HRSEM image of FTO-glass 8 Ohm/square (Pilkington, USA) after reduction as in FIG. 9 and etching.

FIG. 11 shows top-view HRSEM image of ITO/PEN conductive plastic 15 Ohm/square (Peccell, Japan) prior to nano-structuring.

FIG. 12 shows top-view HRSEM image of the ITO/PEN conductive plastic 15 Ohm/square (Peccell, Japan) after reduction.

FIG. 13 shows top-view HRSEM image of ITO/PET conductive plastic 45 Ohm/square (Southwall, USA) prior to nano-structuring.

FIGS. 14A-14B show top-view (14A) and 45°-tilted (14B) images of ITO/PET (45 Ohm/square) after reduction.

FIGS. 15A-15B show HRSEM images of ITO-PET conductive plastic 45 Ohm/square (Southwall, USA) after reduction stronger than that shown in FIG. 14 (15A), and with a higher magnification (15B).

FIG. 16 shows top-view HRSEM image of ITO/PET conductive plastic 45 Ohm/square (Southwall, USA) after reduction stronger than that shown in FIG. 15.

FIG. 17 shows HRSEM image of ITO-glass 8-12 Ohm/square (Delta Technologies, USA) prior to nano-structuring.

FIGS. 18A-18B show top-view (18A) and 45°-tilted (18B) HRSEM images of ITO-glass 8-12 Ohm/square (Delta Technologies, USA) after reduction.

FIGS. 19A-19B show top-view (19A) and 45°-tilted (19B) HRSEM images of ITO/PET conductive plastic 45 Ohm/square (Southwall, USA) after reduction in an electrolyte different than that shown in FIGS. 14-16.

FIGS. 20A-20B show top-view HRSEM image of silver deposited on nanostructured ITO-glass, prepared as described in Example 3 (20A), and FIB image of a cross-section thereof (20B).

FIG. 21 shows 45°-tilted HRSEM image of a sample of a nanostructured ITO-glass after the silver strike (the first step of Ag deposition), as described in Example 3.

FIG. 22 shows top-view HRSEM image of copper deposited on nanostructured ITO-glass, as described in Example 4.

FIG. 23 shows FIB image of a cross-section of copper deposited on nanostructured ITO-glass, as described in Example 4.

FIG. 24 shows top-view HRSEM image of copper deposited on nanostructured FTO-glass, as described in Example 5.

FIG. 25 shows FIB image of a cross-section of copper deposited on nanostructured FTO-glass, as described in Example 5.

FIGS. 26A-26B show top-view (26A) and 45°-tilted (26B) HRSEM images of a nanostructured ITO-glass surface after etching of an electrodeposited silver layer, as described in Example 6.

FIGS. 27A-27B show top-view (27A) and 45°-tilted (27B) HRSEM images of a nanostructured ITO-glass surface after etching of an electrodeposited copper layer, as described in Example 6.

FIGS. 28A-28B show top-view (28A) and 45°-tilted (28B) HRSEM images of a nanostructured ITO-glass surface after etching of an electrodeposited silver layer, as described in Example 6, wherein the etching is longer than that shown in FIGS. 26A-26B.

FIGS. 29A-29B show top-view (29A) and 45°-tilted (29B) HRSEM images of a nanostructured FTO-glass surface after etching of an electrodeposited copper layer, as described in Example 6.

### DETAILED DESCRIPTION OF THE INVENTION

In certain aspects, the present invention relates to a current collector or conductive interconnect comprising a nickel-cobalt alloy for use in photochemical applications.

The composition of the nickel-cobalt alloy used in the various aspects of the present invention may be, without limiting, in the range of nickel 0.1-99.9%, cobalt 99.9-0.1%, preferably nickel 1-99%, cobalt 99-1%, more preferably nickel 2-98%, cobalt 98-2%. In one embodiment, the composition is 41.5% Co, 58.5% Ni. In another embodiment, the composition is 25.8% Co, 74.2% Ni.

The current collector and the conductive interconnect comprising said nickel-cobalt alloy may further be protected by a non-conductive material. Said non-conductive material may be, without being limited to, an inorganic and/or organic coating, a polymeric material such as inorganic-organic polymeric coatings produced as disclosed in International Publication No. WO 2007/015249, herewith incorporated by reference in its entirety as if fully described herein, a hot-melt seal foil, e.g. the resins Surlyn or Bynel (DuPont), with a protective polypropylene cover foil, a low temperature melting glass frit, or a ceramic glaze.

The nickel-cobalt alloys described above may further be deposited on a TCO for use in various applications. Such TCOs constitute another aspect of the present invention and may be any suitable transparent conductive oxide such as, without limiting, fluorine-doped tin oxide (FTO) and tin-doped indium oxide (ITO).

The invention further provides electrodes made of the TCO on which a nickel-cobalt alloy is deposited for photochemical applications. Said photochemical application may be any application in which illumination is performed through an electrode made of a TCO. Examples of such photochemical applications are dye-sensitized solar cells (DSSCs), water purification or photocatalysis. In a most preferred embodiment, the photochemical application is a DSSC.

DSSCs consist of a nanocrystalline, mesoporous network of a wide bandgap semiconductor (the best found was TiO₂), covered with a monolayer of dye molecules. The semiconductor is deposited onto a TCO electrode, through which the cell is illuminated. The TiO₂ pores are filled with a redox mediator, which acts as a conductor, connected to a counter electrode. Upon illumination, electrons are injected from the photo-excited dye into the semiconductor and move towards the transparent conductive substrate, while the electrolyte reduces the oxidized dye and transports the positive charges to the counter electrode.

Small-area DSSCs have achieved a conversion efficiency of 11.3% by the Ecole Polytechnique Federale de Lausanne (EPFL) group, but the efficiency of DSSC modules larger than 100 cm² is still less than 7% (Grätzel, 2006). Scaling up the total device area leads to problems related to efficient current collection (Späth et al., 2003; Dai et al., 2005). The relatively high sheet resistance of both FTO and ITO layers used as current collectors limits the maximal distance from a photoactive point to a current collector to about 1 cm (Kay and Grätzel, 1996). The practical efficiency of a DSSC strictly depends on the series resistance of the cell that lowers the fill factor. This influence becomes more pronounced in cells with larger area. In order to minimize internal resistive losses in a DSSC module with an area of several cm² or larger, interconnects must be applied in series connections or as current collectors. At present, a design with a current collector grid applied to the conducting glass or plastic is prevailing in DSSC modules with an area of 100 cm² and larger.

Metals tested for the grid to reduce resistive losses of TCOs on glass and plastic included Ag, Au, Cu, Al, Ni, but all of these metals were corroded by the iodine electrolyte (Tulloch et al., 2004). The only elements that were found stable to corrosion are Pt, Ti, W and carbon (Tulloch et al., 2004; U.S. Pat. No. 6,555,741); however, Pt is too expensive and Ti, W and carbon are too resistive (Tulloch et al., 2004). At present, the material of choice is silver (Späth et al., 2003; Grätzel, 2000; Arakawa et al., 2006; Dai et al., 2005); however, this metal undergoes rapid corrosion in the presence of iodine-containing redox electrolyte and has to be protected by using high quality polymer- or glass-based protecting layers without pinholes. The protecting layer increases the height of the grid and the distance between the electrodes of DSSC that leads to decreased fill factor and cell efficiency. The main method for producing the current collecting silver grid is screen printing.

The present invention further relates to a dye-sensitized solar cell (DSSC) comprising a transparent conductive oxide (TCO) electrode on which a current collector is deposited, wherein said current collector comprises a nickel-cobalt alloy.

As stated above, the solar energy conversion efficiency of a DSSC strictly depends on the series resistance of the cell that lowers the fill factor. Since scaling up the total DSSC area leads to problems related to efficient current collection, this influence becomes more pronounced in DSSCs with larger area, i.e., in DSSC modules larger than 100 cm². In order to minimize internal resistive losses in a DSSC module with an area of several cm² or larger, interconnects must be applied in series connections or as current collectors.

Thus, in one preferred embodiment, the present invention relates to an array comprising at least two dye-sensitized solar cells (DSSCs) as described above, wherein each two of said at least two DSSCs are connected by a conductive interconnect comprising a nickel-cobalt alloy.

The nickel-cobalt alloys can be deposited on TCOs by different methods such as electrochemical or chemical methods, screen printing and laying wires from said alloy into grooves in the TCO. The criteria for the deposition method selection are high quality, low cost, simplicity and continuous production process. The electrochemical deposition is a widely used, simple and relatively low cost process. In addition, underlayers and overlayers of other conductive materials such as metals can be applied. Wires (or lines) that are electrochemically deposited in optimal conditions are noted for smooth surface, which can be easily protected with an additional overlayer (or overlayers) of conductive or non-conductive material, compared with screen-printed lines, having large internal surface area of huge amount of small particles.

While reducing the present invention to practice, the present inventors have found a simple method for electrochemical or chemical deposition of metals and alloys on a TCO with a very good adhesion of the deposited metal or alloy on the TCO surface. According to this method, the upper layer of the TCO surface is first reduced so as to improve the adhesion of the metal or alloy thereto, and deposition of said metal or alloy is then conducted on the reduced TCO surface.

In still a further aspect, the present invention thus provides a method for electrochemical or chemical deposition of a metal or an alloy on a transparent conductive oxide (TCO) surface, comprising (i) reduction of the upper layer of the TCO surface; and (ii) electrochemical or electroless deposition of said metal or alloy on the reduced TCO surface. In certain embodiments, this method further comprises an etching of the reduced metal obtained in the reduction step (i) prior to electrochemical or electroless deposition of said metal or metal alloy on the reduced TCO surface in step (ii).

The TCO on which metals or alloys can be deposited according to the method of the present invention may be any suitable TCO such as, without being limited to, fluorine-doped tin oxide (FTO), tin-doped indium oxide (ITO), antimony-doped tin oxide, aluminum-doped zinc oxide, gallium-doped zinc oxide, indium-doped zinc oxide, zinc oxide in a slightly reduced form, aluminum-doped cadmium oxide, gallium-doped cadmium oxide, and indium-doped cadmium oxide. In particular embodiments, the TCO used according to the method of the invention is fluorine-doped tin oxide (FTO) or tin-doped indium oxide (ITO).

The metals that can be deposited on a TCO according to the method of the invention include, without limiting, Ag, Cu, Au, Ni, Co, Fe, Pd, Pt, Sn, Pb, Zn, Cd, Ga, In, Tl, Ge, Sb, and Bi. In a particular embodiment, the metal deposited on the TCO according to this method is Ag. The alloy that can be deposited on a TCO according to this method is any alloy of said metals such as, without being limited to, silver-antimony alloy, silver-nickel alloy, silver-palladium alloy, silver-cadmium alloy, silver-lead alloy, silver-indium alloy, silver-cobalt alloy, silver-copper alloy, silver-gold alloy, silver-platinum alloy, silver-bismuth alloy, copper-zinc alloy, nickel-copper alloy, copper-tin alloy, copper-zinc-tin alloy, copper-lead alloy, copper-indium alloy, gold-copper alloy, gold-silver alloy, gold-nickel alloy, gold-cobalt alloy, gold-silver-copper alloy, gold-antimony alloy, gold-indium alloy, nickel-cobalt alloy, nickel-iron alloy, nickel-chromium-iron alloy, nickel-palladium alloy, nickel-tungsten alloy, nickel-tin alloy, nickel-molybdenum alloy, nickel-cobalt-rhenium alloy, nickel-ruthenium alloy, nickel-chromium alloy, nickel-indium alloy, nickel-cobalt-indium alloy, cobalt-indium alloy, and cobalt-tungsten alloy. In a particular embodiment, the alloy deposited on the TCO according to this method is a nickel-cobalt alloy, preferably a nickel-cobalt alloy as defined above.

The reduction of the upper layer of the TCO surface, according to the method of the present invention, may be carried out by any suitable method such as reducing plasma, a chemical process, or an electrochemical process. In a particular embodiment, the reduction of the TCO surface is carried out by an electrochemical reduction, due to its simplicity, rapidity, and low cost. Electrochemical reduction of the TCO surface may be carried out in an electrochemical cell, wherein the TCO is connected to the cathode polarity; the anode is made of an inert insoluble conductive material; and the electrolyte is a diluted solution of at least one salt in water and/or in a polar organic solvent.

The anode used in the electrochemical cell may be made of any inert insoluble conductive material. Examples of such materials include, without being limited to, graphite, platinum, a TCO, and titanium coated with platinum.

In particular embodiments, the electrolyte used for the electrochemical reduction is a diluted solution of at least one salt in either water supplemented with a polar organic solvent, or a polar organic solvent optionally supplemented with water. In particular embodiments, each one of said salts independently consists of an anion such as, without being limited to, halide, nitrate, perchlorate, and sulphate, and a cation such as, without limiting, ammonium, sodium, potassium, aluminum, and magnesium. Particular examples of suitable such salts include, without limiting, NH₄F, NH₄Cl, NH₄Br, NH₄NO₃, NH₄ClO₄, (NH₄)₂SO₄, NaCl, NaNO₃, NaClO₄, Na₂SO₄, KCl, KNO₃, KClO₄, K₂SO₄, Al(NO₃)₃, Mg(NO₃)₂ and combinations thereof. During the operation of said electrochemical cell, a halogen emission could take place at the anode when halide salts are used, and oxygen emission could take place at the anode when nitrate, perchlortate or sulphate salts only are used. At the same time, hydrogen evolution could take place at the cathode.

In certain embodiments, the electrolyte used for the electrochemical reduction of the TCO surface in said electrochemical cell is a diluted solution of at least one salt as defined above in water supplemented with a polar organic solvent, or in a polar organic solvent optionally supplemented with water. In certain particular such embodiments, the polar organic solvent used is a linear or branched C₁-C₆ alkanol such as, without being limited to, methanol, ethanol, propanol, isopropanol, butanol, isobutanol, sec-butanol, tert-butanol, pentanol, neopentanol, sec-pentanol, and hexanol, preferably linear or branched C₁-C₄ alkanol, acetylacetone, glycerin, ethyleneglycol, propylene carbonate, or a mixture thereof.

According to the present invention, the electrochemical reduction of the TCO surface may be carried out in either one step using an electrolyte as defined above or two or more, i.e., two, three, four or more, steps, wherein a different electrolyte as defined above is used in each one of these steps.

The electrochemical reduction of the TCO surface, following which metal ions in said TCO are reduced and form metal nanoparticles and/or nano-islands on the TCO surface, may be followed by an etching process of said nanoparticles and/or nano-islands.

The necessity of etching mainly depends on the physical and chemical properties of both the TCO used and the nanoparticles and/or nano-islands formed, and the influence of said nanoparticles and/or nano-islands on the properties of the final product. For example, if the adhesion of said metal nanoparticles and/or nano-islands to the TCO surface is good, etching of those nanoparticles and/or nano-islands can be avoided; however, if the adhesion of said metal nanoparticles and/or nano-islands to the TCO surface is poor and the nanoparticles and/or nano-islands may thus negatively affect the deposition of the metal or metal alloy on the reduced TCO surface, etching of those nanoparticles and/or nano-islands is necessary.

Particular cases in which etching of the metal nanoparticles and/or nano-islands obtained following reduction of the TCO surface can be avoided are those wherein indium oxide-based TCO such as ITO (containing about 90% of indium oxide and about 10% of tin oxide) are used, and consequently mainly indium nanoparticles and/or nano-islands are formed on the TCO surface. This is principally due to the fact that indium has a good adhesion to many materials, and it is a relatively chemically stable metal, thus can be etched for a reasonable time only in very aggressive and/or hot etching solutions, in which ITO is not stable and can be easily removed or damaged, especially when deposited on plastic substrates. The same or different reasons may be considered before deciding whether etching is required in cases TCOs other than ITO are used.

On the other hand, a particular case in which etching of the metal nanoparticles and/or nano-islands formed is preferable is that wherein the TCO used is FTO, and nickel-cobalt alloy is to be deposited on the nanostructured FTO surface so as to prepare, e.g., a current-collecting grid of a DSSC with iodine containing electrolyte. Since tin nanoparticles and/or nano-islands as those formed in this case are not stable in iodine containing electrolytes, they may negatively affect the chemical stability of the final product, and should thus be etched prior to nickel-cobalt alloy deposition.

The etching process is a chemical process carried out in an aqueous and/or polar organic solvent solution selected from an acid or a base solution; a complexing agent solution; a solution of an oxidizing agent together with a complexing agent; or a solution of an oxidizing agent together with an acid or a base. Suitable polar organic solvents may be selected from linear or branched C₁-C₄ alkanols as defined above, acetylacetone, acetonitrile, glycerin, ethyleneglycol, propylene carbonate, and mixtures thereof. Suitable acid solutions include, without limiting, solutions of hydrochloric acid, nitric acid, sulfuric acid, acetic acid, oxalic acid, citric acid, sulfamic acid, and mixtures thereof; and suitable base solutions include, without limiting, solutions of sodium hydroxide, potassium hydroxide, ammonium hydroxide, tetramethylammonium hydroxide, tetraethylammonium hydroxide, tetrapropylammonium hydroxide, and tetrabutylammonium hydroxide. Suitable oxidizing agents include, without being limited to, iodine, chlorine, bromine, hydrogen peroxide, FeCl₃, CuCl₂, K₂Cr₂O₇, KMnO₄, NaClO, (NH₄)₂S₂O₈, and Ce(NH₄)₂(NO₃)₆; and suitable complexing agents include, without limiting, ammonium chloride, ammonium bromide, ammonium iodide, ammonium citrate, ammonium hydroxide, sodium citrate, potassium-sodium tartrate, Trilon B (ethylenediaminetetraacetic acid disodium or tetrasodium salts), potassium cyanide, and sodium cyanide.

According to the present invention, the etching of the reduced metal nanoparticles and/or nano-islands may be carried out in either one step or two or more, i.e., two, three, four or more, steps, wherein a different solution as defined above is used in each one of these steps.

As found while reducing the present invention to practice, the adhesion of a metal or metal alloy to a TCO surface on which it is deposited can be greatly improved by first reducing the TCO upper surface and optionally etching the metal nanoparticles obtained. As particularly found, the outcome of this process is a TCO having a modified surface, more specifically nanostructured upper surface being characterized by nano-holes, nano-grooves, nano-nets, and/or chains of nano-holes; and optionally nanoparticles and/or nano-islands of a metal reduced from metal ions in the TCO surface, wherein said metal nanoparticles each independently has a spherical, oval, distorted spherical, or distorted oval shape; and said metal nano-islands each independently has an irregular shape. The practical significance of this nanostructured upper surface is a substantially increased roughness compared with that of said TCO surface prior to that process. Furthermore, in cases no etching is performed, the metal nanoparticles and/or nano-islands formed on the TCO surface act as deposition centers that initiate and improve the adhesion with the deposited metal or metal alloy. The reduction of the TCO upper surface, optionally followed by etching of the metal nanoparticles and/or nano-islands formed, may therefore be referred to as a “nano-structuring” process, resulting in a TCO having a nanostructured upper surface being characterized by nano-holes, nano-grooves, nano-nets and/or chains of nano-holes; and optionally nanoparticles and/or nano-islands of a metal reduced from metal ions in said TCO.

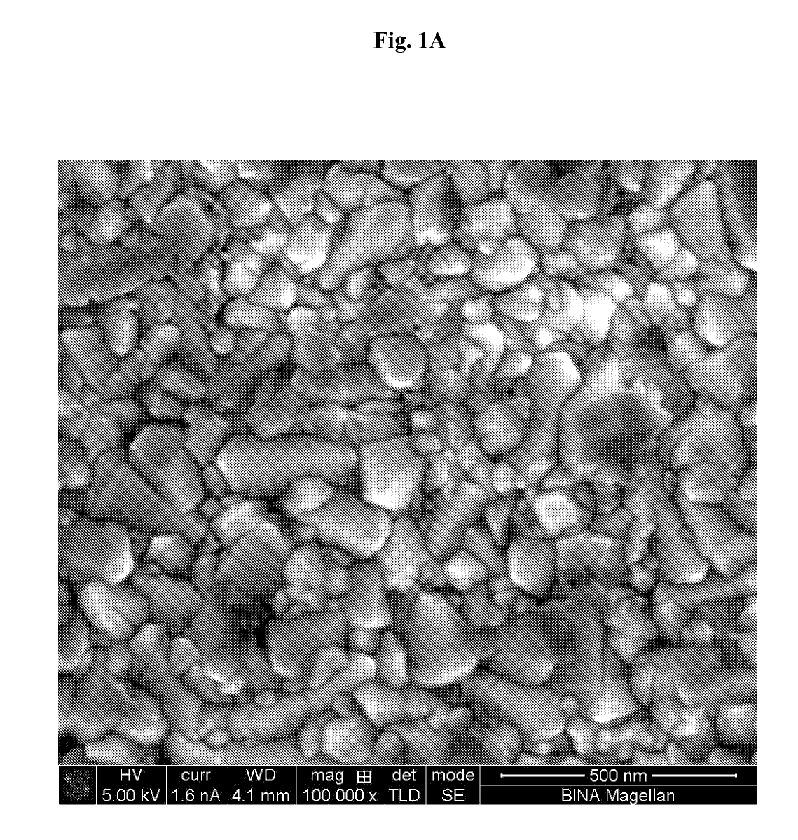

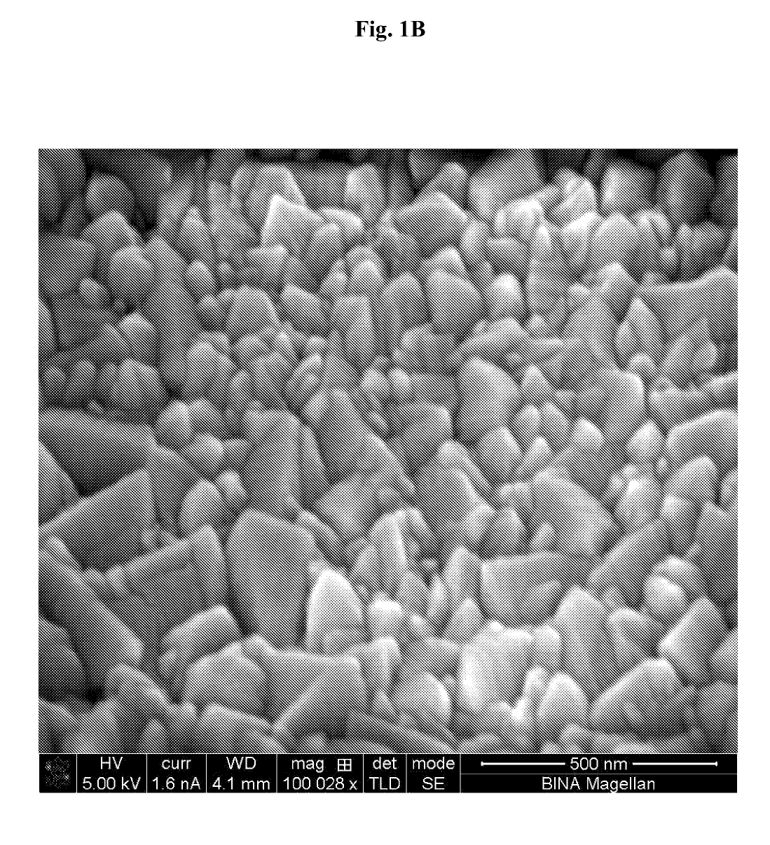

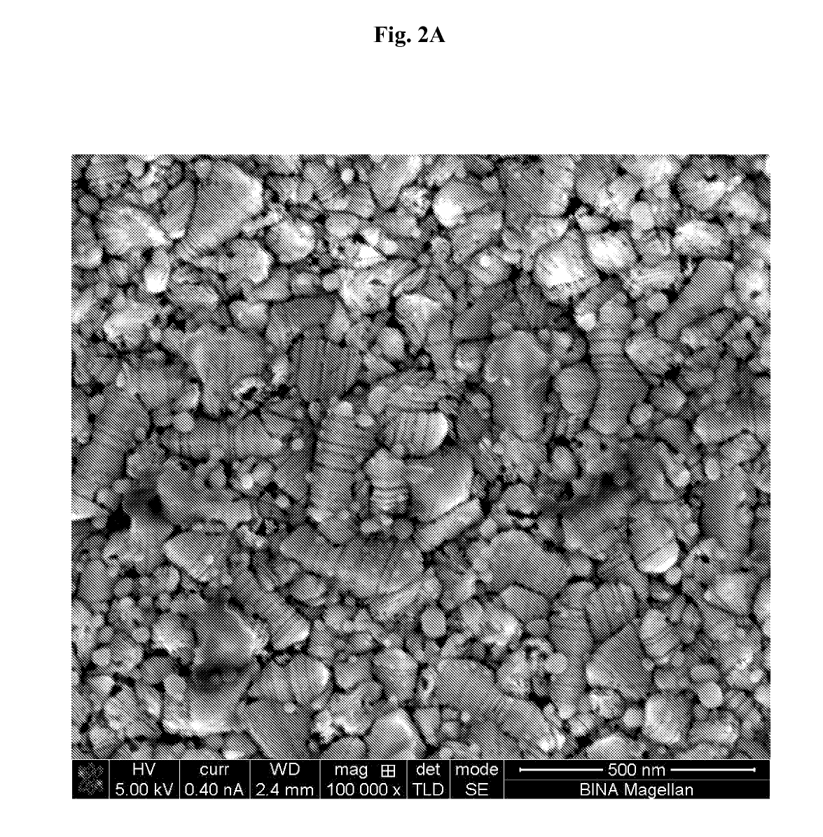

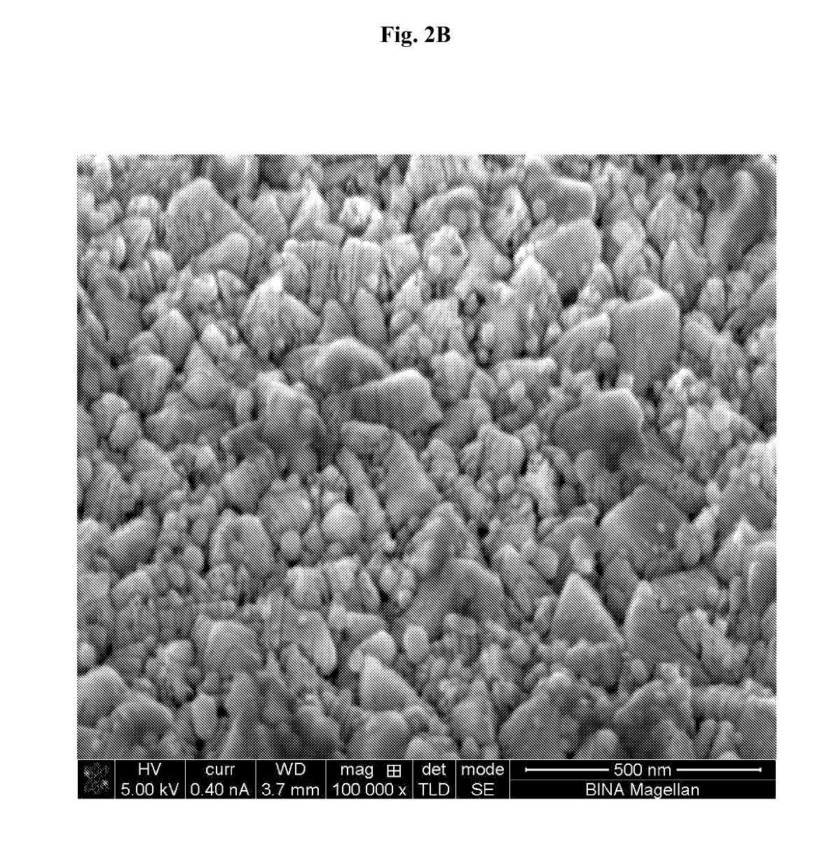

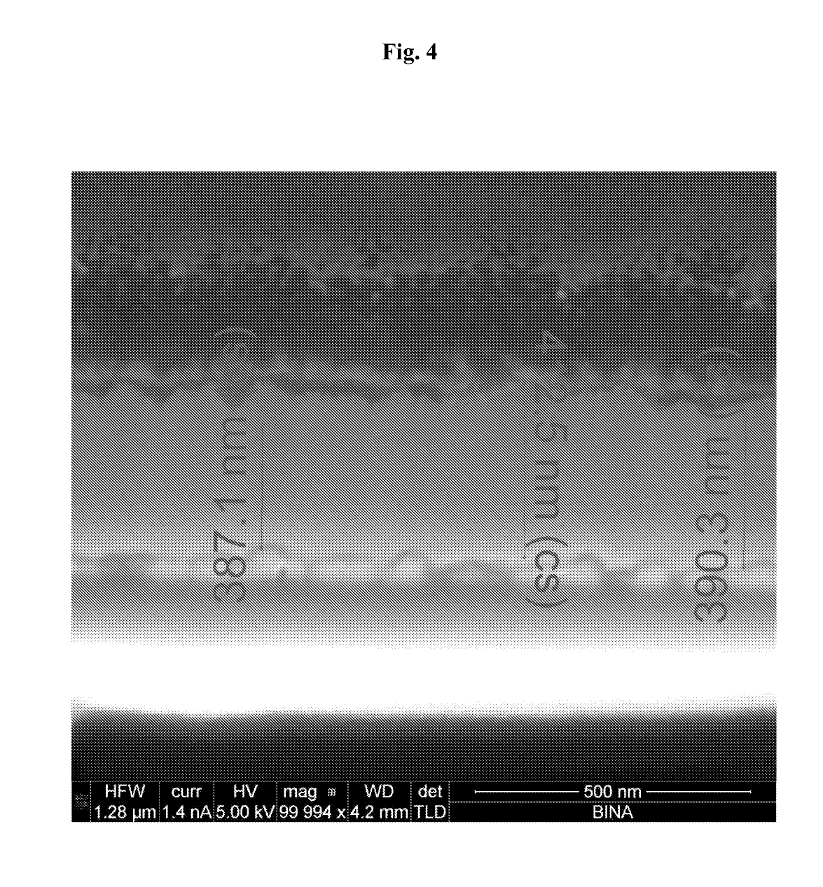

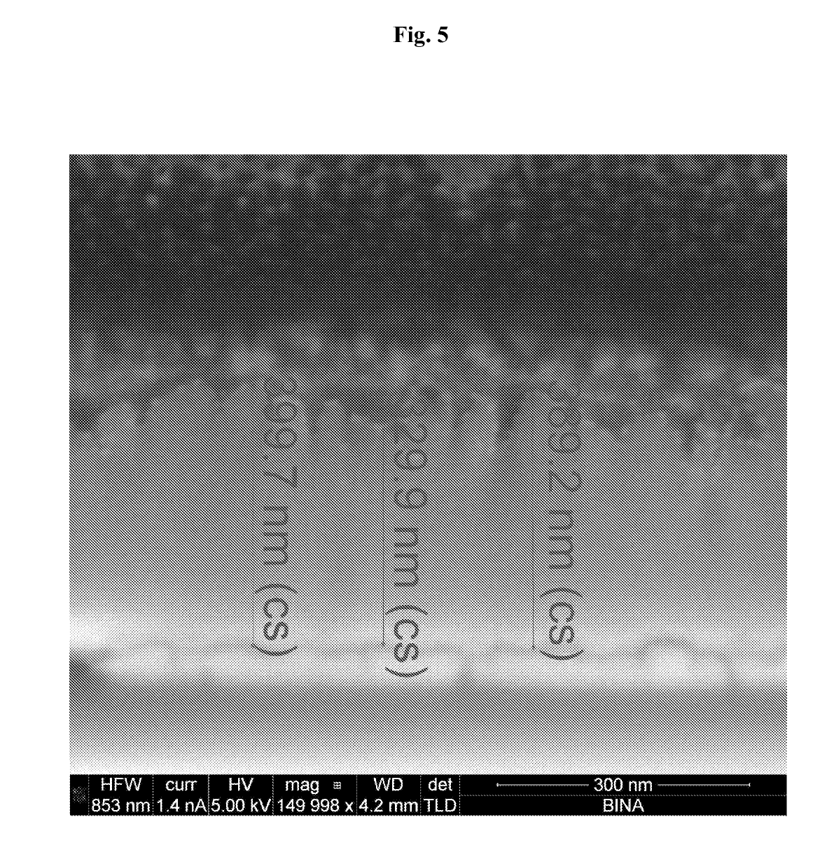

FIGS. 1-3 show top-view and 45°-tilted HRSEM images of FTO-glass 15 Ohm/square prior to nano-structuring, after reduction, and after both reduction and etching, respectively. FIB images of cross-sections of said FTO prior to and after nano-structuring are shown in FIGS. 4 and 5, respectively. As clearly observed from these images, the reduction of the FTO surface, during which tin ions in the upper layer of said surface are reduced and leave the surface, results in the creation of nano-size holes and grooves in said surface, and in the formation of spherical or oval tin nanoparticles and nano-islands on said surface, i.e., in substantial increase in the FTO surface roughness. The etching of the reduced tin results in removal of tin nanoparticles and nano-islands, although the roughness of the FTO surface following the etching is yet remarkably higher than that of the FTO surface prior to the nano-structuring process.

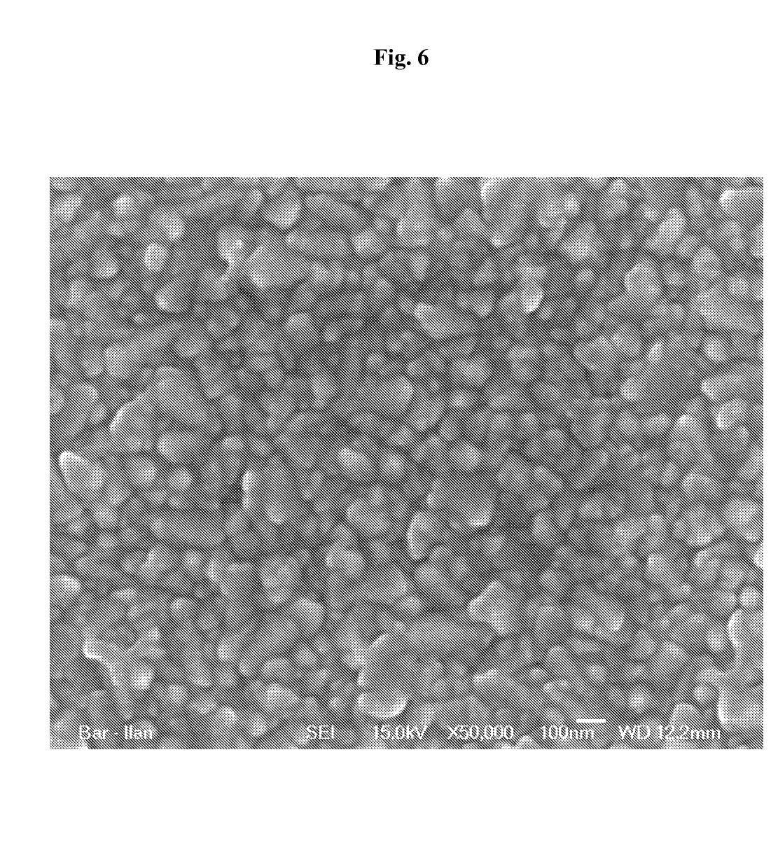

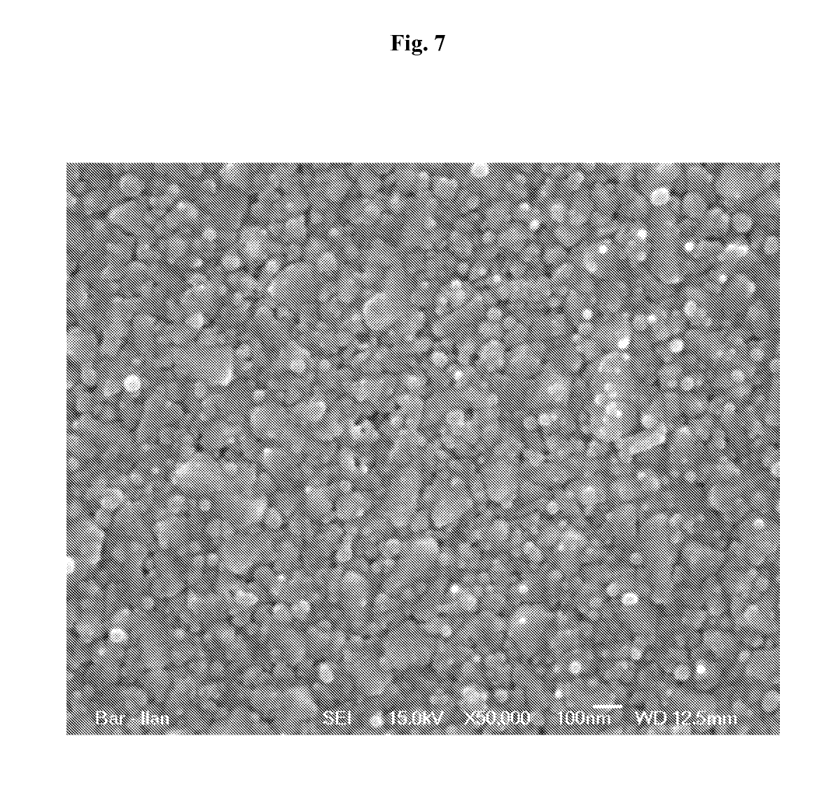

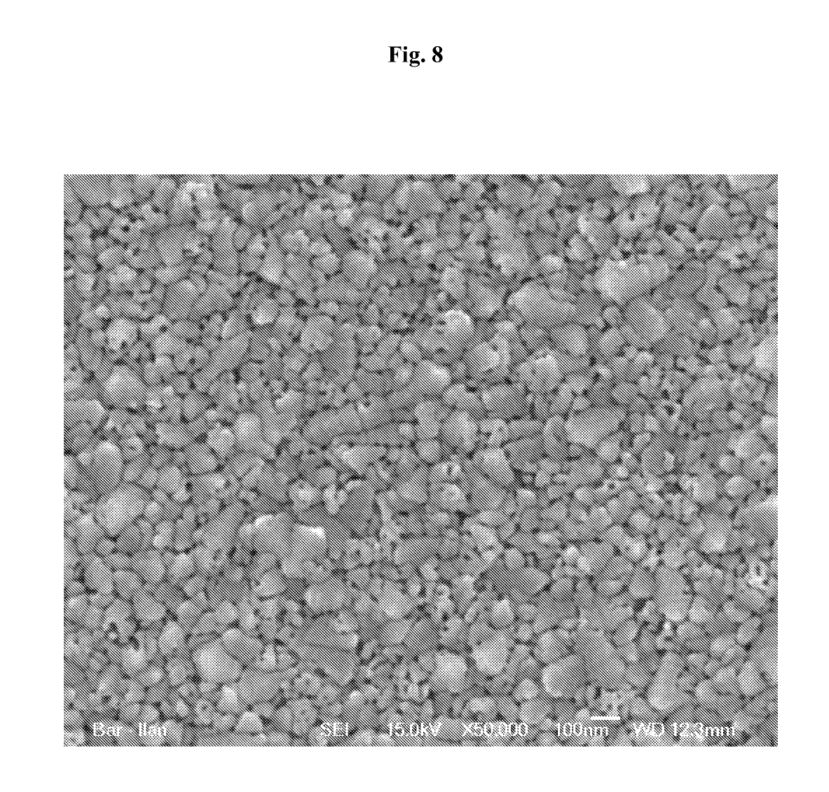

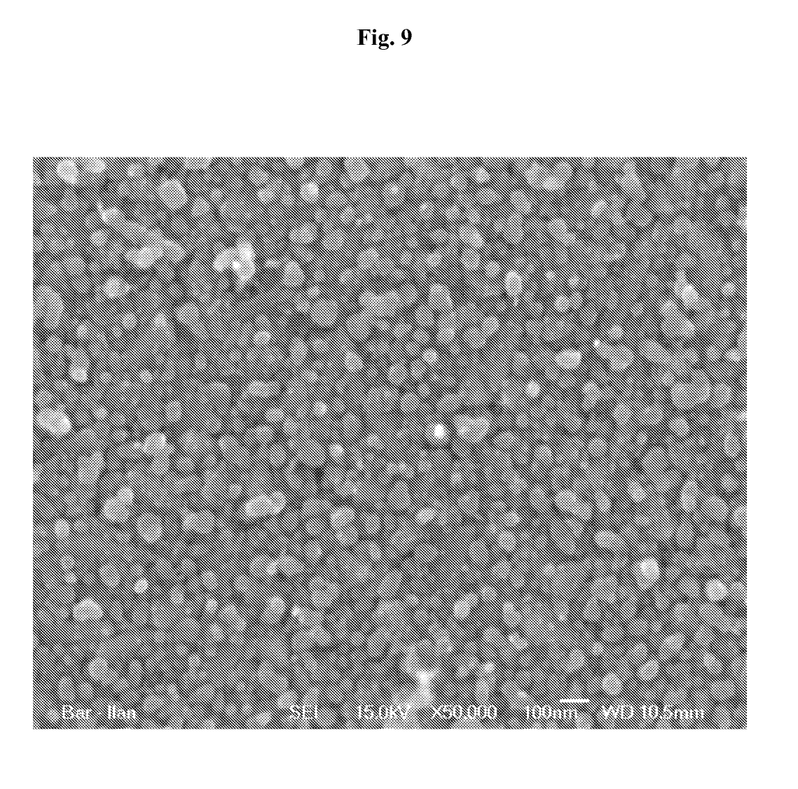

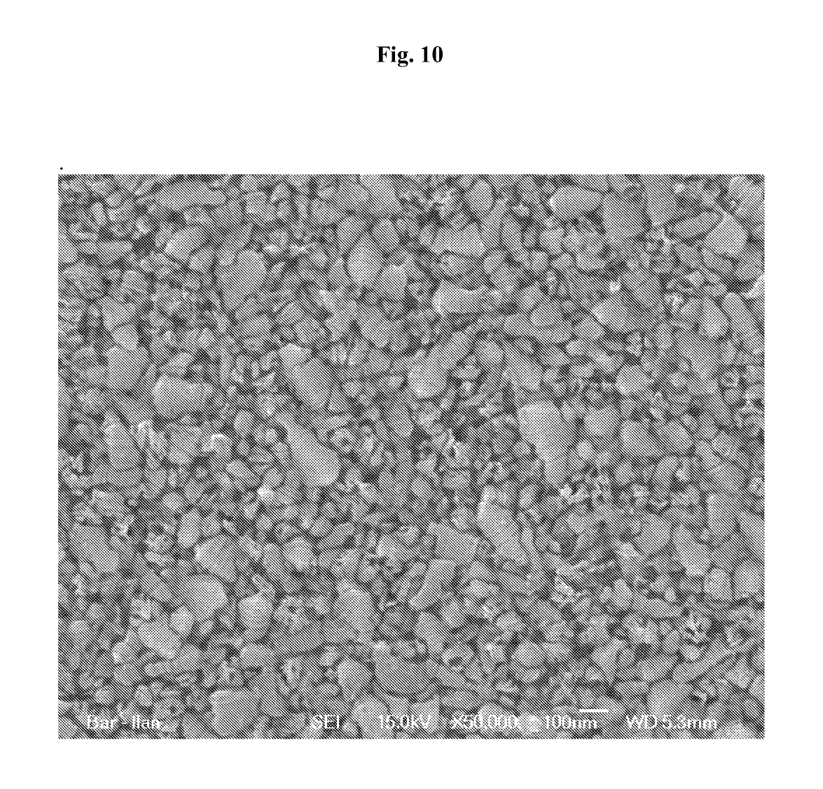

Similar effects are observed when using FTO-glass 8 Ohm/square as shown in FIGS. 6-10. Specifically, FIGS. 6-8 show top-view HRSEM images of FTO-glass 8 Ohm/square prior to nano-structuring, after reduction, and after both reduction and etching, respectively. The difference between this FTO (8 Ohm/square) and that shown in FIGS. 1-3 (15 Ohm/square), both reduced and etched under the same conditions, seems to be in the ratio between the nano-holes and nano-grooves in the nanostructured FTO surface. In fact, it looks that more nano-holes and less nano-grooves appear in the FTO 8 Ohm/square upper surface compared with those appearing in the FTO 15 Ohm/square upper surface. Nevertheless, when the reduction extent in the case of FTO 8 Ohm/square is increased, the tin nanoparticles and nano-islands formed become bigger; and etching of the reduced tin on the FTO surface then results in a very rough surface characterized by nano-grooves and a lot of bigger nano-holes, as shown in FIGS. 9-10.

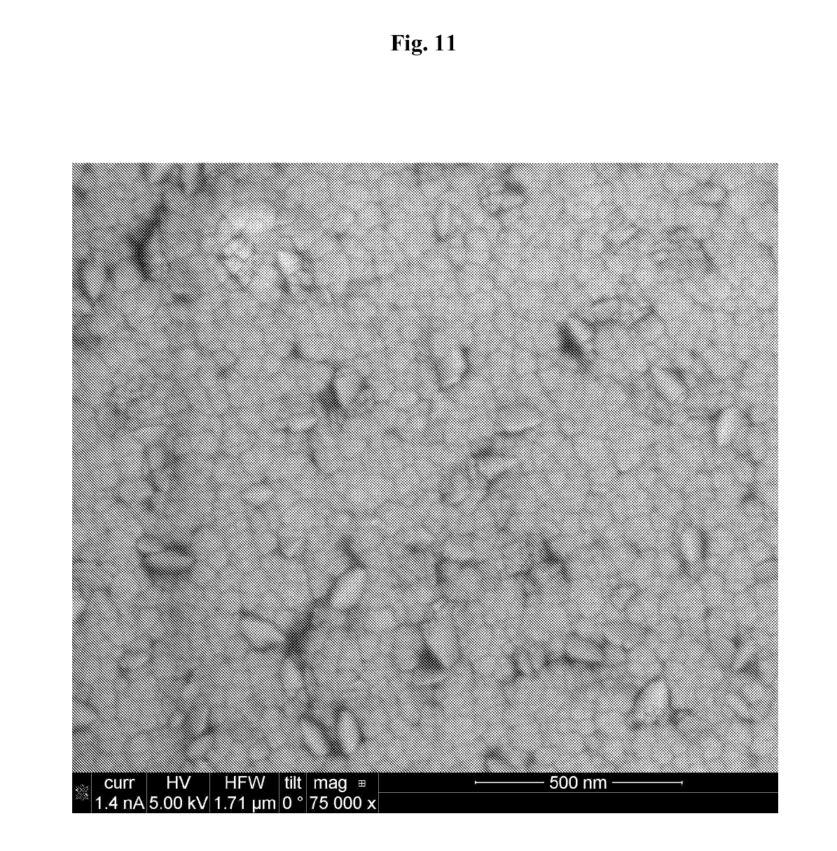

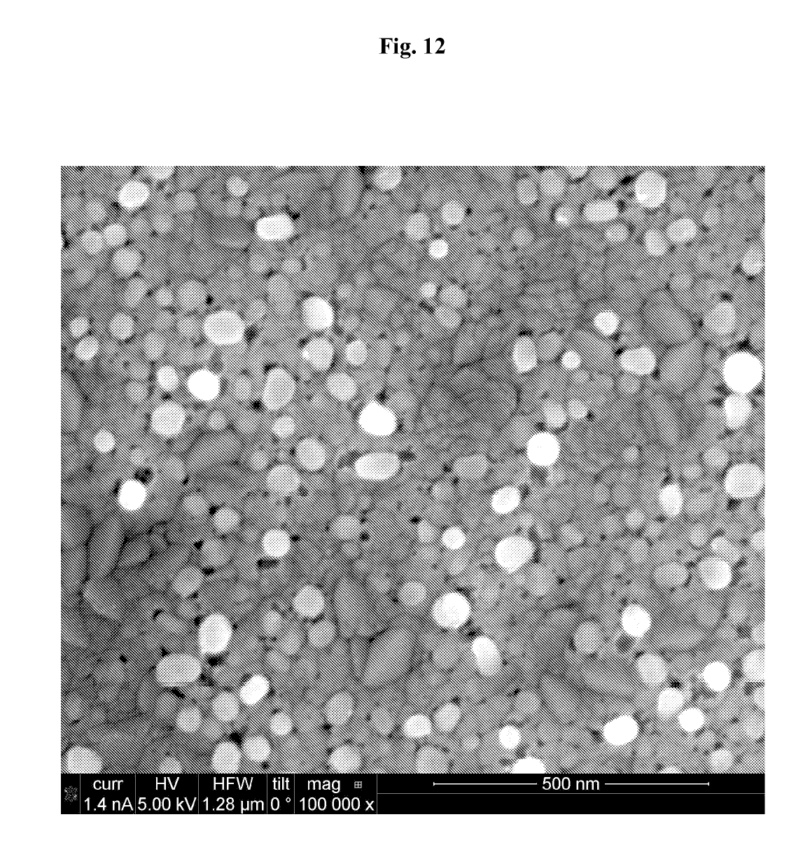

Similar effects can also be seen for ITO on glass and plastic substrates, but due to the differences in the chemical and physical properties between indium and tin, and the particular properties of indium discussed above, etching of the indium nanoparticles resulting from the reduction of indium ions in the ITO surface can be avoided. FIGS. 11-12 show top-view HRSEM images of ITO/PEN conductive plastic (15 Ohm/square) prior to nano-structuring and after reduction, respectively. As observed, the reduction of the ITO surface results in spherical and/or oval indium and tin nanoparticles on the reduced ITO surface as well as in nano-size holes in the surface, thus in substantial increase in the roughness of the ITO surface.

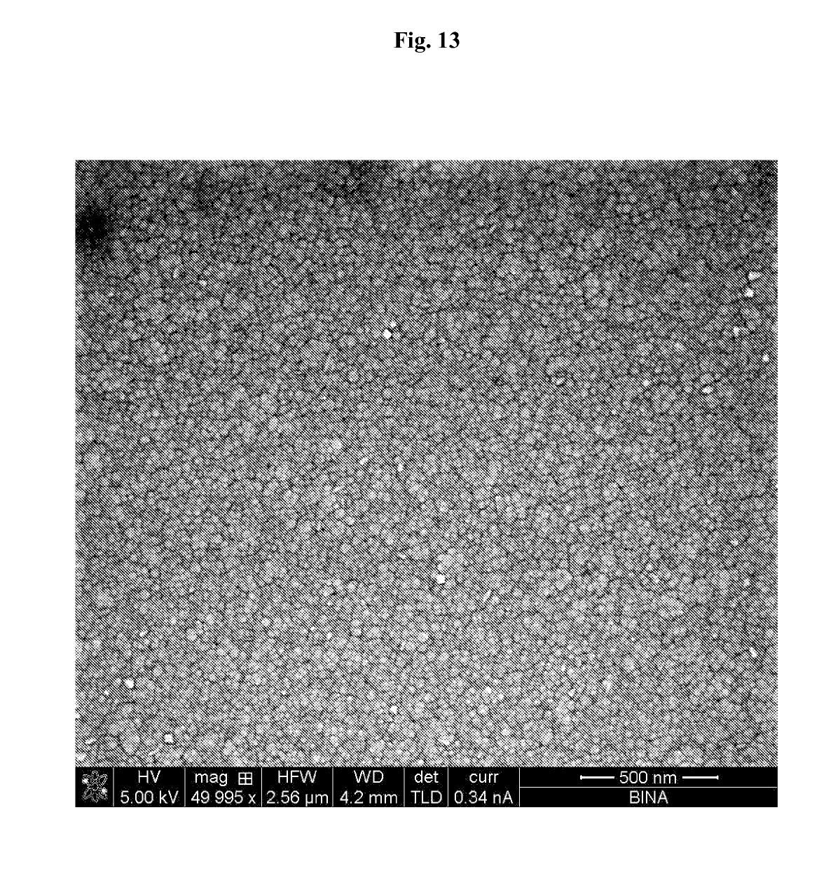

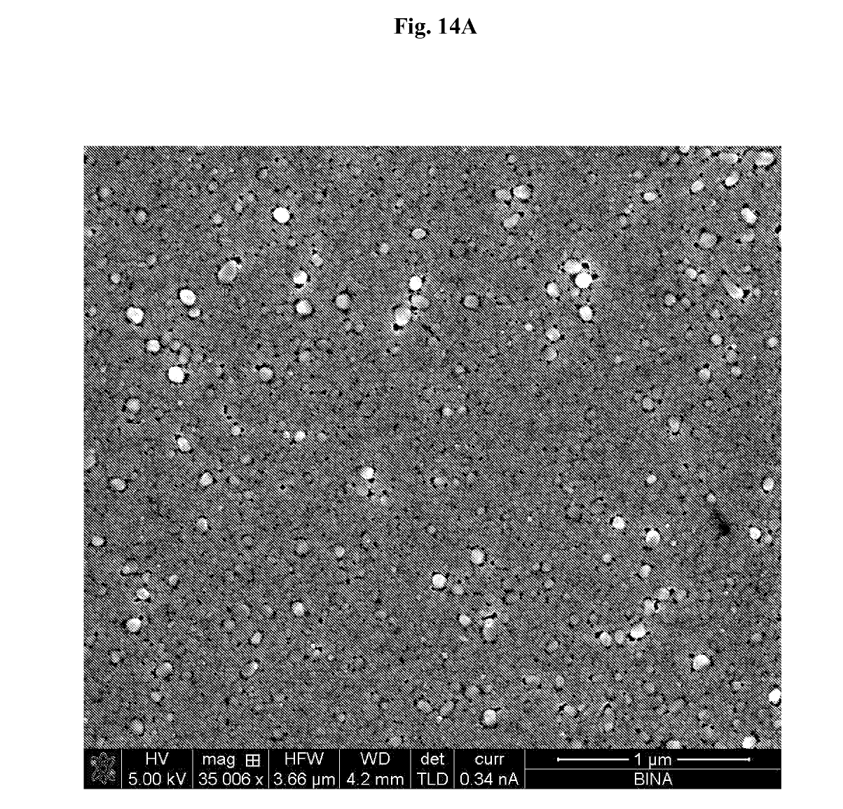

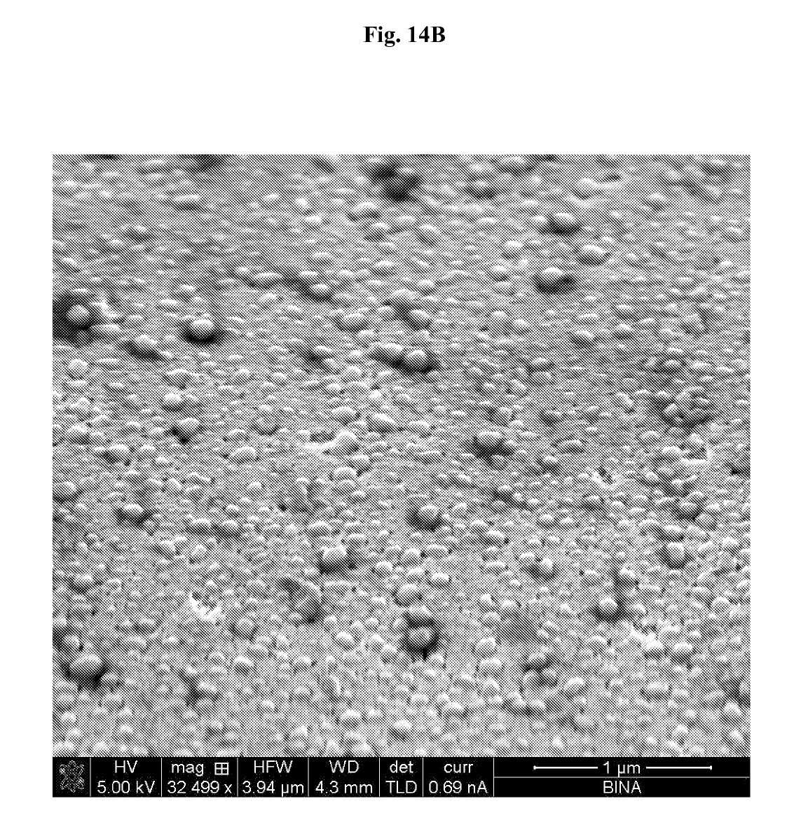

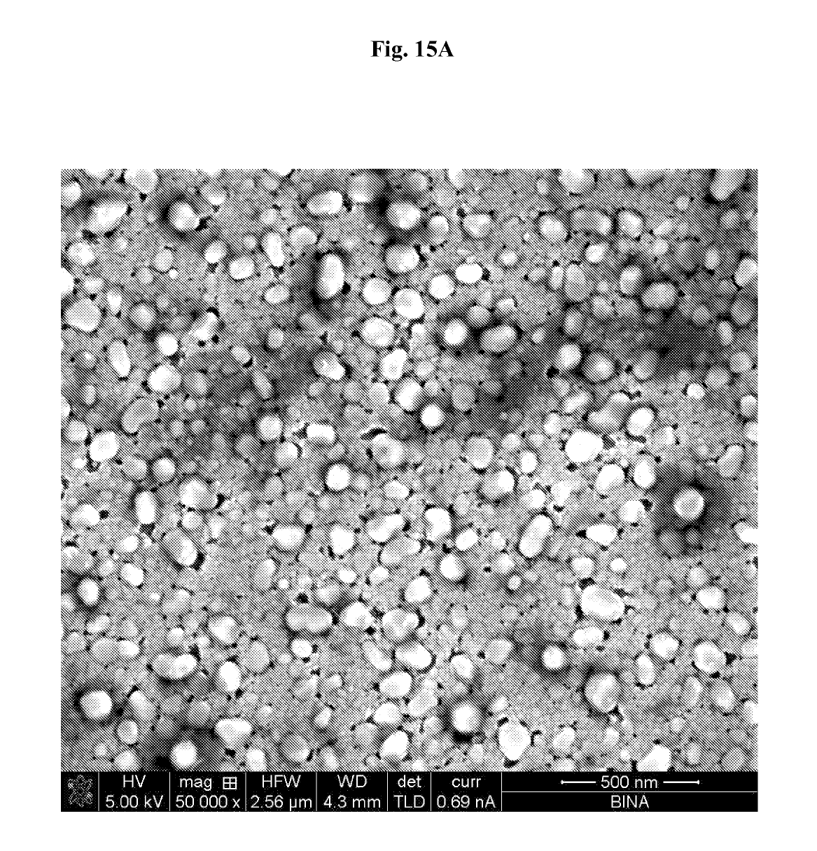

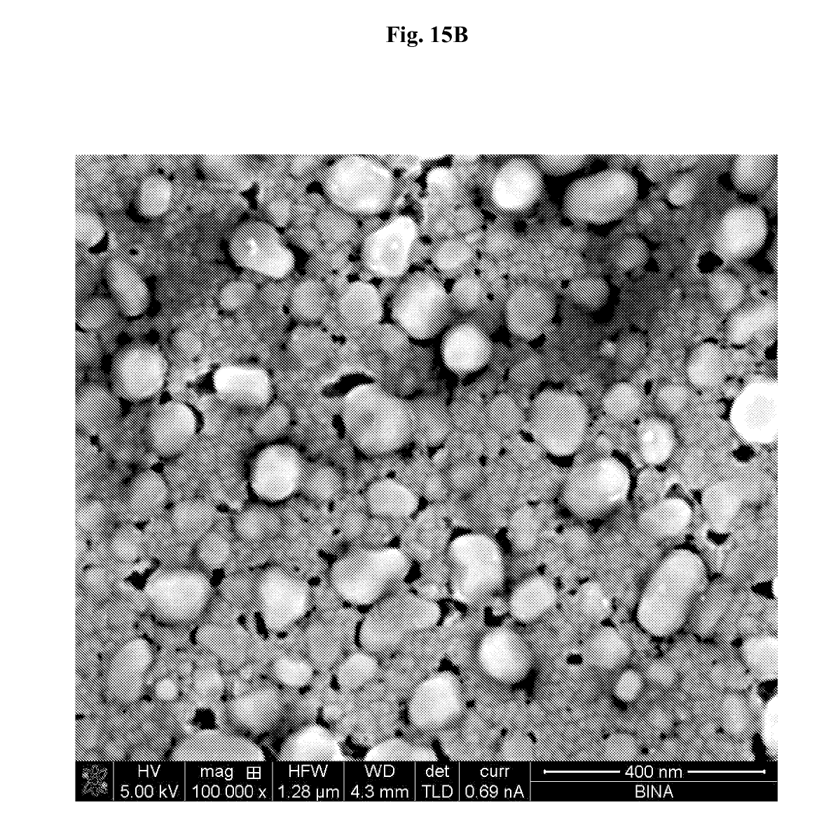

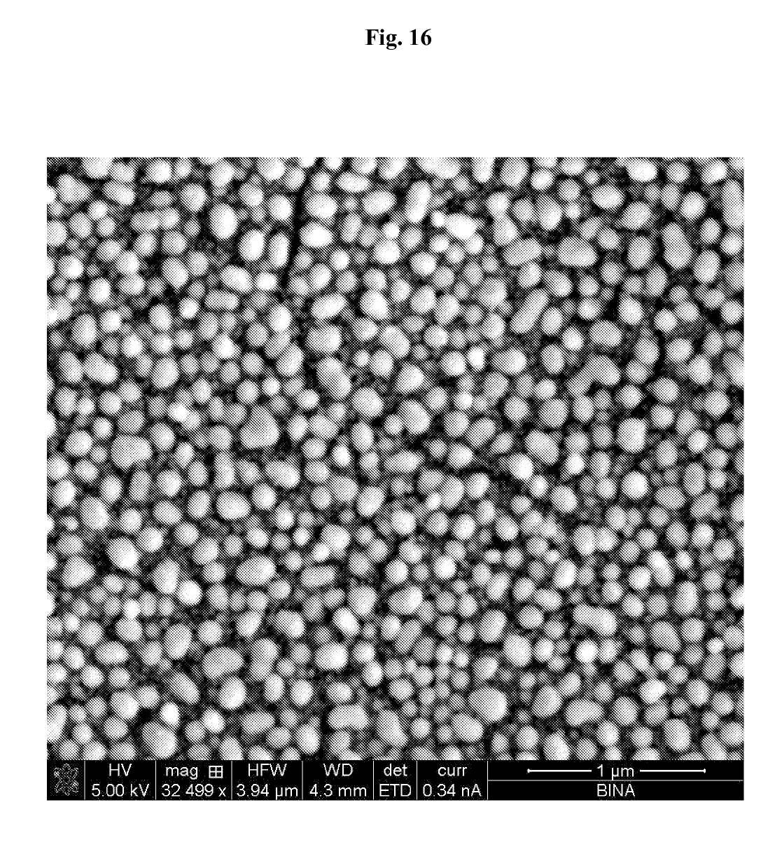

Similar HRSEM images are shown for ITO on PET conductive plastic in FIGS. 13-16. More particularly, FIG. 13 shows top-view image of ITO/PET (45 Ohm/square) prior to nano-structuring, and FIG. 14 shows top-view and 45°-tilted images of said ITO/PET after reduction. Images of the ITO/PET after a stronger reduction are shown in FIG. 15, and an image of said ITO/PET after even stronger reduction is shown in FIG. 16. As clearly observed, increase in the reduction degree results in both bigger size and higher amount of indium and tin nanoparticles on the reduced ITO surface. As clearly shown in FIG. 14B, the metal nanoparticles obtained following reduction of metal ions in the ITO upper surface leave the reduced surface, thus creating nano-holes in the surface, and are positioned on the top of the reduced surface. The roughness of the reduced surface is significantly higher than that of the ITO surface prior to the nano-structuring process.

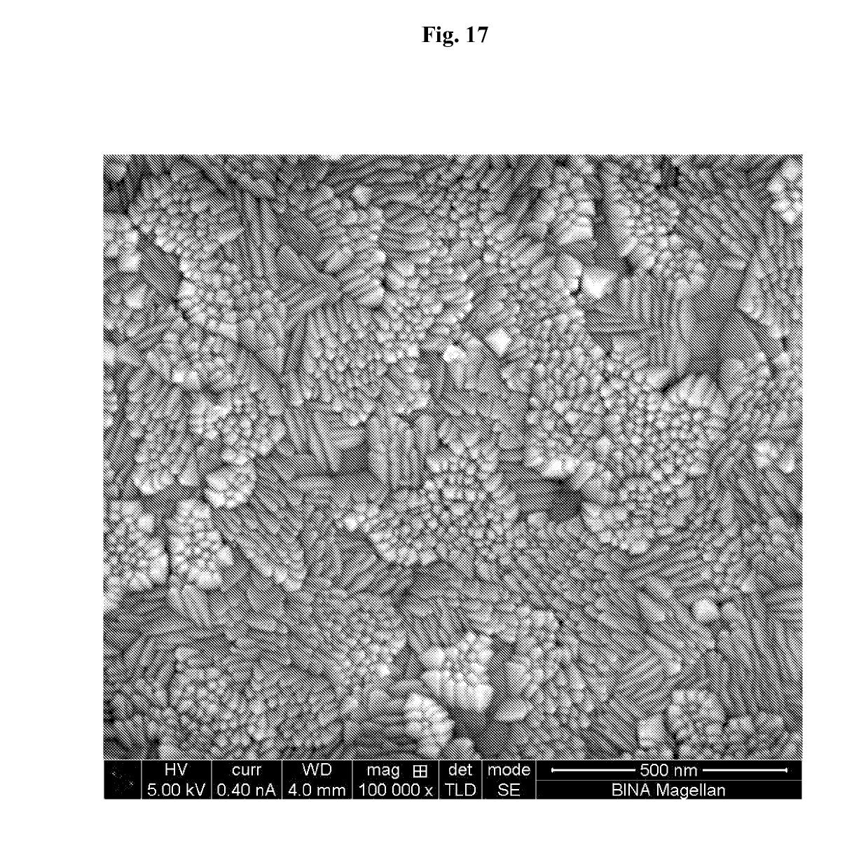

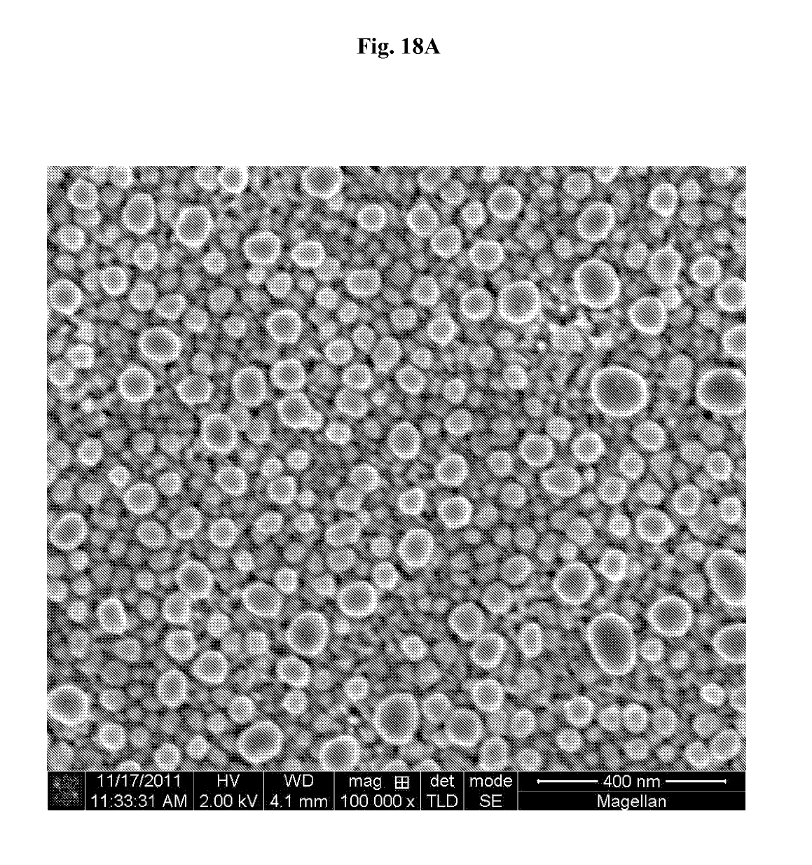

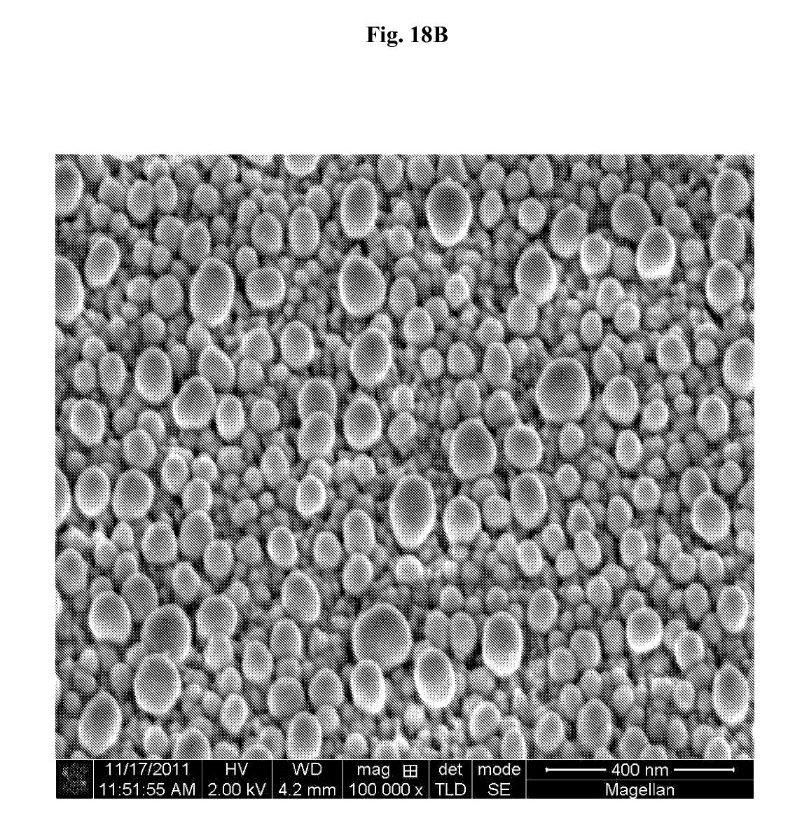

FIG. 17 shows top-view image of ITO-glass (8-12 Ohm/square) prior to nano-structuring, and FIG. 18 show top-view and 45°-tilted images of said ITO-glass after reduction.

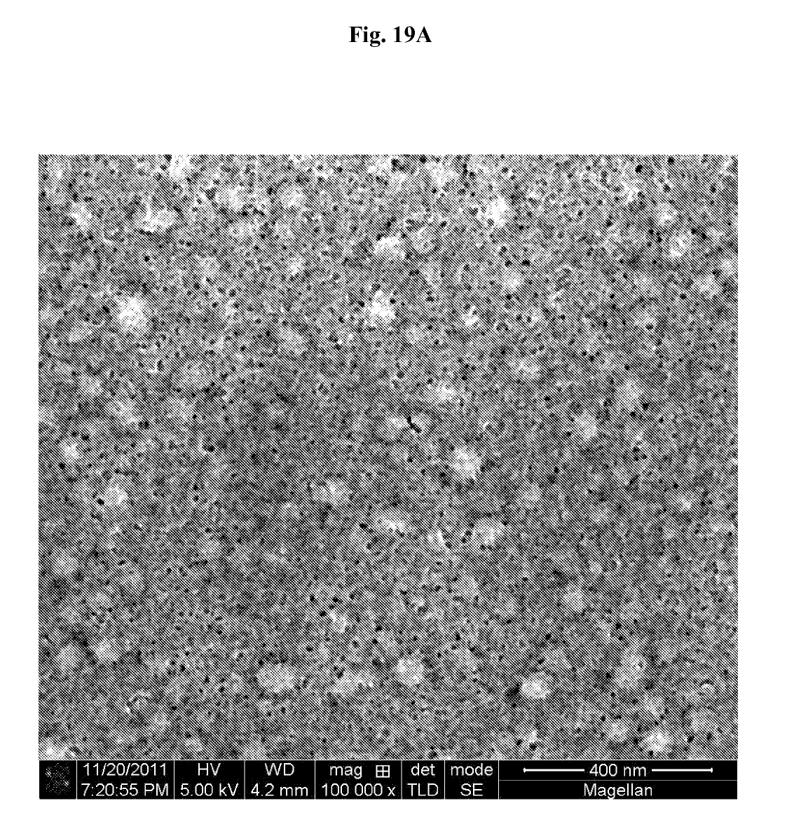

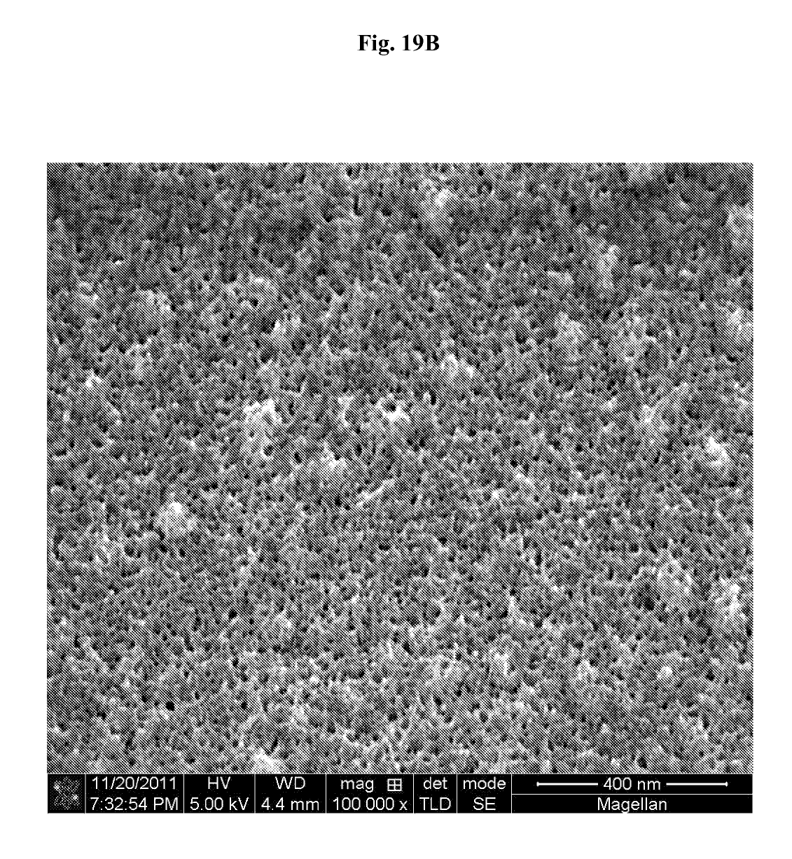

FIG. 19 shows top-view and 45°-tilted images of ITO/PET (45 Ohm/square) as shown in FIG. 13, after reduction with a different electrolyte, indicating that by modifying either the reduction or etching process, or both, the shape of the nanostructured TCO surface can be changed. As observed in this particular case, the change of the electrolyte used in the reduction process results in a nanostructured surface being quite different from that shown in FIGS. 14-16 and characterized by a net of modified ITO, i.e., a great number of nano-holes, with indium and tin nanoparticles and nano-islands deposited on top of said net of modified ITO.

In still another aspect, the present invention thus relates to a transparent conductive oxide (TCO) comprising a metal oxide either doped with ions of a chemical element or in a slightly reduced form, wherein said TCO has a nanostructured upper surface being characterized by (i) nano-holes, nano-grooves, nano-nets and/or chains of nano-holes; and optionally (ii) nanoparticles and/or nano-islands of a metal reduced from metal ions in said TCO.

The articles “a” and “an” are used herein to refer to one or to more than one, i.e., to at least one, of the grammatical object of the article, unless context clearly indicates otherwise. By way of example, “a chemical element” means one element or more than one element, and “a metal” means one metal or more than one metal.

The TCO according to this aspect of the present invention may be any suitable transparent conductive oxide as defined above, e.g., fluorine-doped tin oxide (FTO) or tin-doped indium oxide (ITO), antimony-doped tin oxide, aluminum-doped zinc oxide, gallium-doped zinc oxide, indium-doped zinc oxide, zinc oxide in a slightly reduced form, aluminum-doped cadmium oxide, gallium-doped cadmium oxide, or indium-doped cadmium oxide, wherein fluorine-doped tin oxide (FTO) and tin-doped indium oxide (ITO) are preferred.

As stated above, upon reduction of the upper layer of a TCO surface, metal ions in said TCO surface are reduced and leave the surface, thus creating nano-holes, nano-grooves, nano-nets and/or chains of nano-holes in the surface; and forming metal nanoparticles and/or nano-islands positioned on the surface. The phrase “metal ions in said TCO” as used herein refers to all metal ions reduced during the nano-structuring process, i.e., to those of the metal oxide as well as other metal ions if present in the particular TCO used. For example, when fluorine-doped tin oxide (FTO) is used, the metal ions reduced during the nano-structuring process are tin ions only, and therefore the nanoparticles and/or nano-islands formed on the FTO upper surface are made of tin only. In contrast, when tin-doped indium oxide (ITO) is used, the metal ions reduced during the nano-structuring process are both indium and tin ions, and the nanoparticles and/or nano-islands formed on the ITO upper surface are thus composed of both indium and tin.

The term “nano-holes” as used herein refers to nanometric holes in the upper layer of the reduced TCO surface, resulting from reduction of metal ions in the upper layer of said TCO surface to metal nanoparticles following which said metal nanoparticles leave the surface. The size of those nanometric holes may be in a range of 0.1-100 nm in diameter. The terms “nano-grooves”, “nano-nets” and “chains of nano-holes” as used herein refer to different shapes or configuration of nano-holes resulting from reduction of metal ions in the upper layer of the reduced TCO surface depending on the TCO nature and reduction conditions, i.e., number of reduction steps applied, electrolyte or electrolytes, cathode potential, current density and duration in each reduction step. Nano-grooves possess an oblong shape with a length much larger than the width. The length of the nano-grooves may be equal to a length of individual TCO crystals, and may be in a range of 10-400 nm, and the width of the nano-grooves may be in a range of 0.01-20 nm.

The terms “nanoparticles” and “nano-islands” as used herein refers to different types of nanometric metal forms formed on the upper layer of the reduced TCO surface, following reduction of metal ions in the upper layer of said TCO surface under different reduction conditions. More particularly, the term “nanoparticles” refers to nanometric metal particles having a regular shape, e.g., spherical or oval shape, or distorted spherical or oval shape, and the term “nano-islands” refers to nanometric metal areas having an irregular shape. The size of the metal nanoparticles may be in a range of 0.1-100 nm in diameter, and the size of the metal nano-islands may be in a range of 1-200 nm.

In a particular such aspect, the invention relates to a TCO having a nanostructured upper surface as defined above, wherein said nanostructured upper surface obtained by a method comprising reduction of metal ions in the upper layer of a surface of a TCO; and optionally etching of the reduced metal nanoparticles and/or nano-islands obtained. In certain embodiments, the metal nanoparticles formed on the TCO upper surface upon reduction of metal ions in the TCO upper surface have a spherical, oval, distorted spherical, or distorted oval shape; and the metal nano-islands have an irregular shape.

In yet another aspect, the present invention relates to a transparent conductive oxide (TCO) having a nanostructured upper surface as defined above, further comprising, on said nanostructured upper surface, a layer of a metal or an alloy thereof.

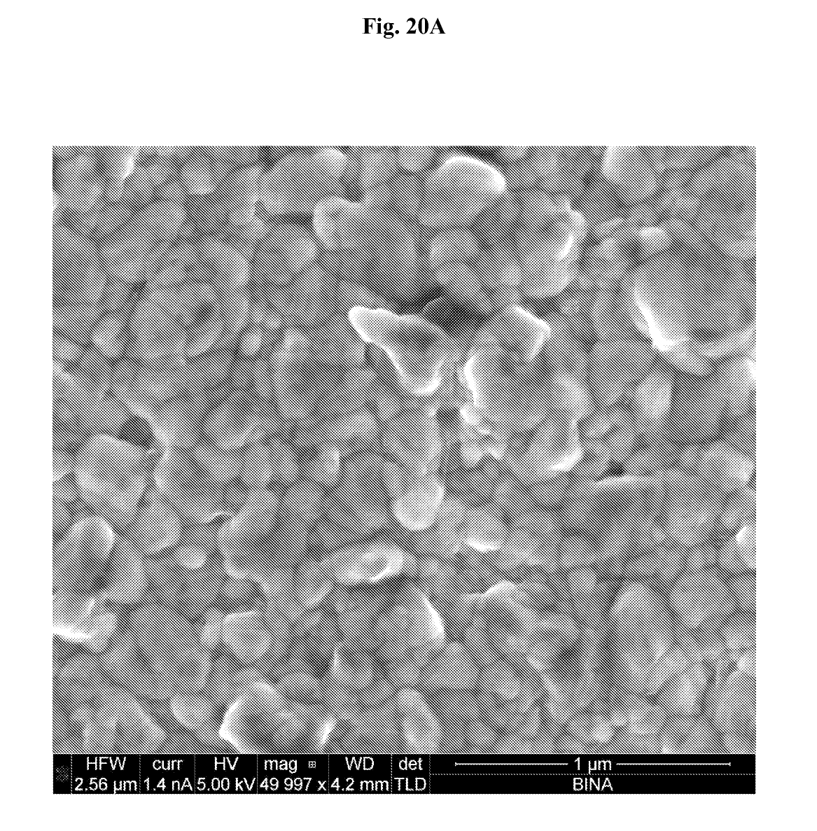

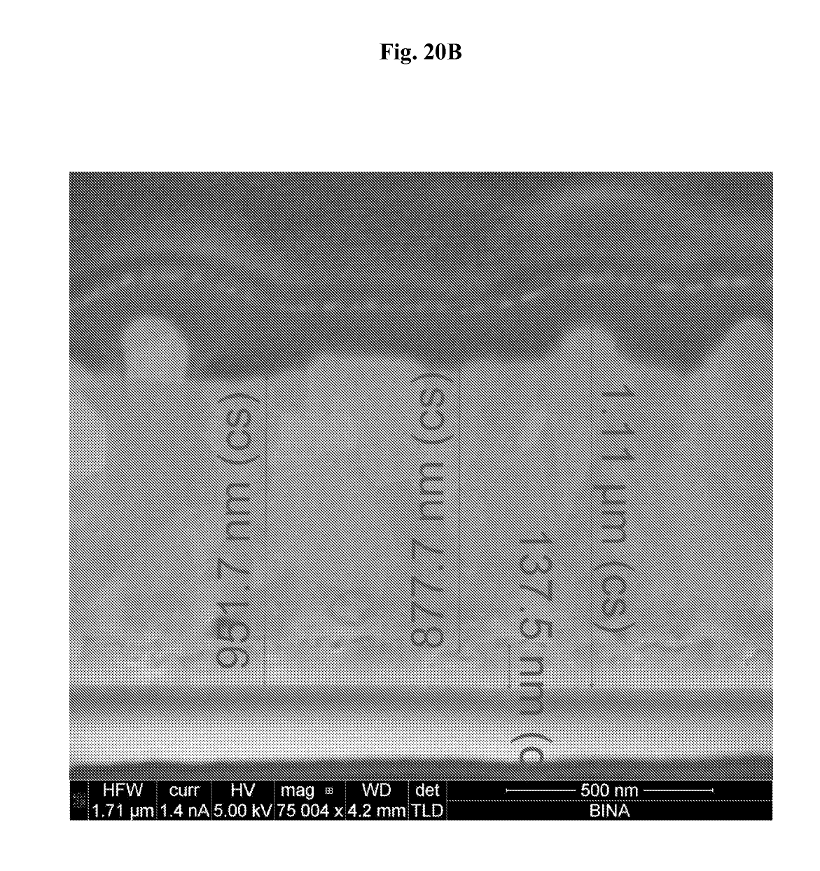

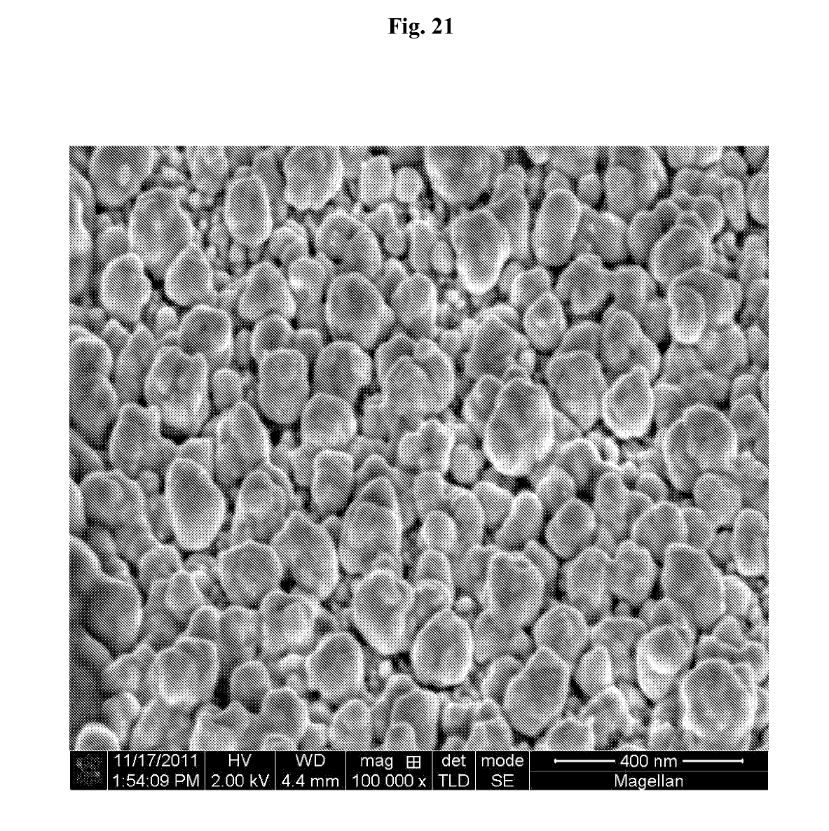

Example 3 herein shows electrochemical fabrication of silver layer on ITO-glass (8-12 Ohm/square) in three steps from three electrolytes having different compositions. A comparison between an HRSEM image of the nanostructured ITO-glass after the first step of silver deposition (FIG. 21) and the HRSEM image of the reduced ITO-glass (FIG. 18) indicates that at the beginning of the electrochemical deposition, silver is preferably deposited on nanoparticles of the reduced metal, i.e., indium and tin, positioned on the nanostructured surface, and consequently, the shape of these nanoparticles is changed from spherical or oval to irregular, and the size of the metallic nanoparticles is increased. As shown in a FIB image of a cross-section of the final product (FIG. 20B), the silver layer is dense with a thickness of about 880 nm, and it is very well attached to the ITO due to silver penetration into the nano-holes in the reduced ITO surface, and good adhesion between the nanoparticles of the reduced metal and the silver.

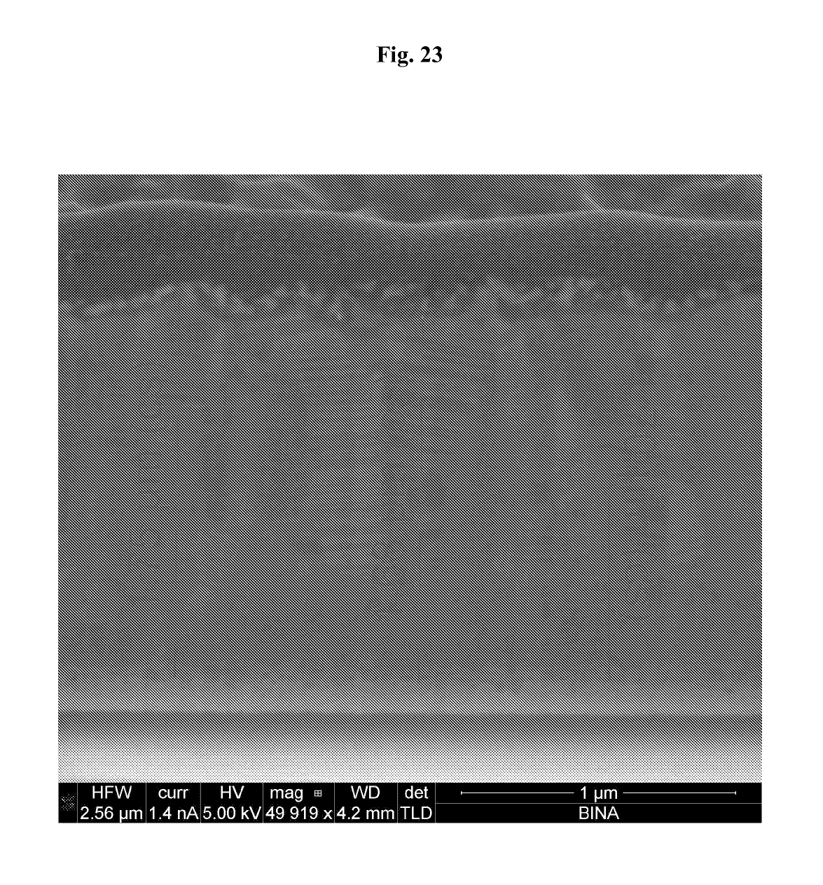

Example 4 shows electrochemical fabrication of copper layer on ITO-glass (8-12 Ohm/square), in processes similar to that described in Example 3. As shown in a FIB image of a cross-section of the final product (FIG. 23), the copper layer on the ITO-glass is dense with thickness of about 1.7 μm, and it is very well attached to the ITO.

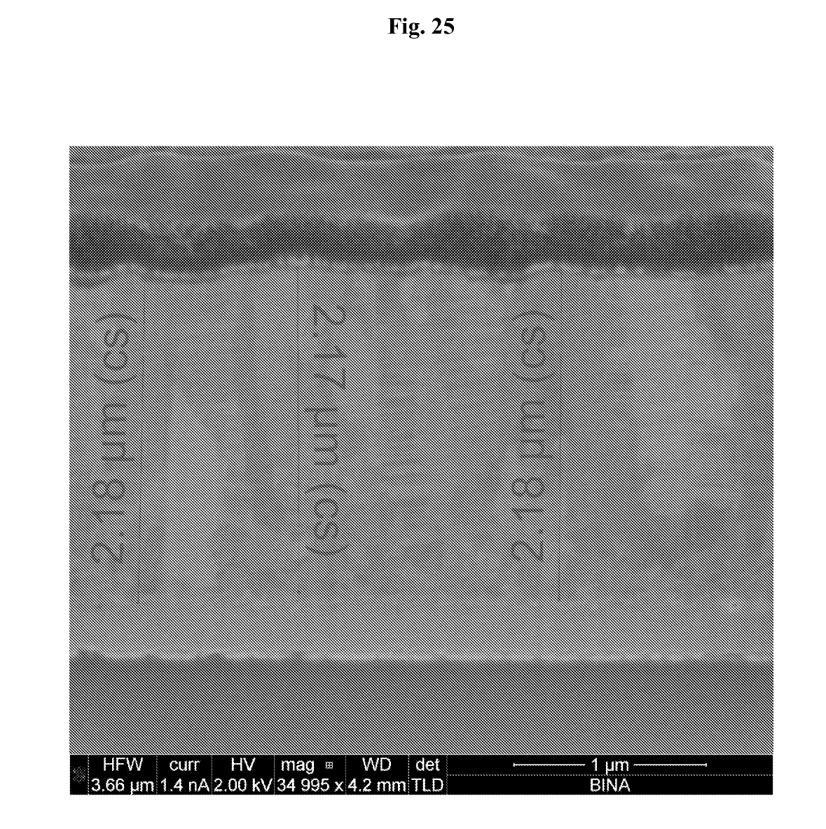

Example 5 shows electrochemical fabrication of copper layer on FTO-glass (15 Ohm/square), using a process comprising both reduction of the FTO upper surface and etching of the tin nanoparticles formed. A FIB image of a cross-section of the final product (FIG. 25) shows that the copper layer is dense with a thickness of 2.18 μm, and it is very well attached to the FTO due to very good penetration of copper into the nano-holes and nano-grooves in the nanostructured FTO surface.

In certain embodiments, the metal or metal alloy layer deposited on the nanostructured upper layer of the TCO is obtained by electrochemical or electroless deposition of said metal or metal alloy on said nanostructured upper surface.

Examples of metals that may be electrochemically or chemically deposited on said nanostructured upper layer include, without being limited to, Ag, Cu, Au, Ni, Co, Fe, Pd, Pt, Sn, Pb, Zn, Cd, Ga, In, Tl, Ge, Sb, and Bi. Metal alloys that may be electrochemically or chemically deposited on said nanostructured upper layer include any alloy of each one of the metal listed above, e.g., silver-antimony alloy, silver-nickel alloy, silver-palladium alloy, silver-cadmium alloy, silver-lead alloy, silver-indium alloy, silver-cobalt alloy, silver-copper alloy, silver-gold alloy, silver-platinum alloy, silver-bismuth alloy, copper-zinc alloy, nickel-copper alloy, copper-tin alloy, copper-zinc-tin alloy, copper-lead alloy, copper-indium alloy, gold-copper alloy, gold-silver alloy, gold-nickel alloy, gold-cobalt alloy, gold-silver-copper alloy, gold-antimony alloy, gold-indium alloy, nickel-cobalt alloy, nickel-iron alloy, nickel-chromium-iron alloy, nickel-palladium alloy, nickel-tungsten alloy, nickel-tin alloy, nickel-molybdenum alloy, nickel-cobalt-rhenium alloy, nickel-ruthenium alloy, nickel-chromium alloy, nickel-indium alloy, nickel-cobalt-indium alloy, cobalt-indium alloy, and cobalt-tungsten alloy.

TCOs according to the present invention, having a nanostructured upper surface as defined above on which a layer of metal or metal alloy is deposited, can be applied in various optoelectronic, photovoltaic and photochemical devices.

In a further aspect, the present invention provides an optoelectronic device comprising a transparent conductive oxide (TCO) comprising a metal oxide and having a nanostructured upper surface as defined above, further comprising, on said nanostructured upper surface, a layer of a metal or an alloy thereof. In one embodiment, the optoelectronic device of the invention is an organic light-emitting diode (OLED) device. In such particular embodiments, the metal or alloy layer is deposited on said nanostructured TCO upper surface according to a pattern of a metallic busbar (grid) structure so as to increase the conductivity of a substrate on which said TCO is deposited and uniformly spread the current over the substrate to ensure homogenous emission. Preferred such OLED devices are those wherein a layer of silver or copper, having the highest conductance, or an alloy of one or both of those metals is deposited on the nanostructured TCO upper surface.

In still a further aspect, the present invention provides a photovoltaic cell comprising a transparent conductive oxide (TCO) comprising a metal oxide and having a nanostructured upper surface as defined above, further comprising, on said nanostructured upper surface, a layer of a metal or an alloy thereof. In certain embodiments, the photovoltaic cell of the invention is an organic thin film (OPV) solar cell, a compound semiconductor thin film solar cell such as Cu(In,Ga)Se₂, i.e., CIGS, or CdTe semiconductor thin film solar cell, or a dye sensitized solar cell (DSSC). In such particular embodiments, the metal or alloy layer is deposited on said nanostructured upper surface according to a pattern of a metallic current-collecting grid so as to increase the conductivity of a substrate on which said TCO is deposited and reduce resistive losses. Preferred OPV and compound semiconductor thin film solar cells are those wherein a layer of silver or copper, or an alloy of one or both of those metals, is deposited on the nanostructured TCO upper surface. Preferred DSSCs wherein non-corrosive hole conductors or electrolytes such as spiro-OMeTAD (2,2′,7,7′-tetrakis-(N,N-di-p-methoxyphenyl amine)-9,9′-spirobifluorene) and cobalt^{(+2/+3)} redox couple based electrolytes are applied, are those wherein a layer of silver or copper, having the highest conductance, or an alloy of one or both of those metals is deposited on the nanostructured TCO upper surface. Preferred DSSCs wherein corrosive hole conductors or electrolytes such as iodine containing electrolytes are applied are those wherein a layer of a nickel-cobalt alloy, nickel-cobalt-indium alloy, nickel-tungsten alloy, nickel-cobalt-manganese alloy, nickel-cobalt-tungsten alloy, nickel-ruthenium alloy, or nickel-cobalt-ruthenium alloy is deposited on the nanostructured TCO upper surface.

In yet a further aspect, the present invention provides a photochemical water splitting device comprising a transparent conductive oxide (TCO) comprising a metal oxide and having a nanostructured upper surface as defined above, further comprising, on said nanostructured upper surface, a layer of a metal or an alloy thereof. In certain embodiments, the metal or alloy layer is deposited on said nanostructured upper surface according to a pattern of a metallic current-distributing and/or current collecting grid so as to increase the conductivity of a substrate on which said TCO is deposited and reduce resistive losses. Preferred photochemical water splitting devices wherein non-corrosive materials are applied are those wherein a layer of silver or copper, or an alloy of one or both of those metals, is deposited on the nanostructured TCO upper surface. Preferred photochemical water splitting devices wherein corrosive materials are applied are those wherein a layer of a nickel-cobalt alloy, nickel-cobalt-indium alloy, nickel-tungsten alloy, nickel-cobalt-manganese alloy, nickel-cobalt-tungsten alloy, nickel-ruthenium alloy, or nickel-cobalt-ruthenium alloy is deposited on the TCO upper surface.

The invention will now be illustrated by the following non-limiting Examples.

### EXAMPLES

### Example 1

### Electrochemical Fabrication of Nickel-Cobalt Wires on FTO Glass and DSSC Prepared Therefrom

FTO glass with a size of 70 mm×40 mm (8 Ohm/square, Hartford Glass Co. Inc., USA) was thoroughly cleaned with trichloroethylene, mild soap and ethanol, washed with water and distilled water, and dried in a filtered air stream. The FTO glass was then covered with a mask prepared from a chemical resistant paint (Enplate Stop-Off No 1, Enthone-OMI, Inc., which is represented in Israel by Amza Surface Finishing Technologies), leaving uncovered areas for 4 wires, each area having dimensions of 55 mm×0.8 mm, with a space of 7.7 mm between, and an area for a collector stripe at one short side of the substrate with a length of 30 mm and a width of 3 mm at a distance of 5 mm from the edge of the substrate.

After drying the mask at room temperature for about 1 h, hydrophilization of the mask was performed for a better wetting of the mask boundaries with the FTO glass. This step is desirable in cases hydrophobic masking materials are used, preventing the accumulation of hydrogen bubbles on the boundaries of the mask and the TCO, which interfere with the following electrochemical reduction of the upper layer of said TCO. The hydrophilization of the mask was performed in a solution similar to the “sensitization solution” (see hereinbelow): 2.5 g SnCl₂.2H₂O and 20 ml HCl (1.19 g/cm³) in 250 ml distilled water, at room temperature without stirring for 10 min. After washing with water and distilled water, the uncovered areas of the FTO were further cleaned in a solution similar to the “reduction solution” (see hereinbelow): 0.25 g NH₄Cl in 250 ml distilled water, under stirring with magnetic stirrer at room temperature, at the anodic polarity with an inert cathode (Pt cathode was used), with constant current density of 20 mA/cm² and during 1 min This cleaning procedure can be different for different masking materials, depending on the properties of the masking material used.

Then, the reduction of the upper layer of the FTO glass was performed by treating the FTO glass with a solution of 0.25 g NH₄Cl in 250 ml distilled water (herein “reduction solution”), under stirring with magnetic stirrer at room temperature, at the cathode polarity with an inert anode (Pt anode was used). The constant current density was 10 mA/cm² and the duration was 50 sec. The color of the uncovered areas of the FTO glass changed from colorless to light brown due to the tin reduction.

After washing with distilled water, the substrate was chemically treated with a solution of 2.5 g SnCl₂.2H₂O and 20 ml of HCl (1.19 g/cm³) in 250 ml distilled water (herein “sensitization solution”), at room temperature without stirring for 10 min. The color of the FTO glass changed again to colorless due to the reduced tin etching In addition, during said treatment, tin (II) ions adsorb onto the surface and hydrolyze during following washing with water and distilled water. The hydrolysis products adsorb onto the etched FTO glass surface, which then becomes hydrophilic and, as a result, the adhesion of the metallic ions to the surface in the next step of electrochemical or electroless deposition is improved.

For electrochemical deposition of a nickel-cobalt alloy, an electrolyte containing NiSO₄.6H₂O 60 g/l, CoSO₄.7H₂O 15 g/l, H₃BO₃ 25 g/l and NaCl 10 g/l, with pH=5.6, was prepared. The deposition was carried out at room temperature, under constant current density of 5 mA/cm² for 60 min with a nickel anode. After washing and drying the substrate, the mask was removed. The chemical composition of the alloy was 41.5% Co and 58.5% Ni, and the height of the wires above the FTO glass surface was 7.5 μm.

The passivation of the alloy was carried out in a solution of K₂Cr₂O₇ 60 g/l at room temperature for 10 min. After washing and drying the substrate, a new mask from the chemical resistant paint mentioned hereinabove was prepared, leaving uncovered areas for the same as above 4 wires, each area having dimensions of 55 mm×1.5 mm, with a space of 7 mm between, and an area for the collector stripe. After drying the mask at room temperature for about 1 h, a thin dielectric Al₂O₃-coating was deposited as disclosed in International Publication No. WO 2007/015249. In particular, 20 mg of iodine, 4 ml of acetone and 5 μl of nitric acid were added to 250 ml of ethanol, and the mixture was stirred with magnetic stirrer for 24 h in a closed vessel. Using an inert atmosphere glove box, 0.5 ml of Al(OsecC₄H₉)₃ were placed in a bottle and hermetically sealed. The sealed bottle was transferred outside the glove box where, under ambient conditions, the aforesaid ethanolic solution was added to the Al(OsecC₄H₉)₃, inside the bottle, under vigorous stirring. The solution was sonicated in an ultrasound bath and then stirred, during 24 h. Subsequently, 2 ml of deionized water were added, and the solution was stirred for additional 24 h, resulting in ˜250 ml transparent sol (the color of the sol gradually changed from yellow to colorless). The sol was left for aging in a closed vessel without stirring at ambient conditions for 7 days, after which it was ready for EPD. The electrophoretic cell contained two electrodes placed vertically at a distance of 40 mm in the aforesaid transparent sol. The FTO substrate with wires served as the cathode and a F-doped-SnO₂ conductive glass served as a counter-electrode. The FTO substrate with the wires was electrically connected via the collector stripe. The alumina coating was deposited only onto the wires area. The EPD process was performed at room temperature under constant current, using a Keithley 2400 Source Meter as a power supply. The current density was 0.2 mA/cm² and the sol-gel EPD duration was 3 min. After drying the FTO substrate at ambient conditions, the masking paint was mechanically removed and the substrate was washed with ethanol and dried, first at ambient conditions and then by thermotreatment, during which temperature was slowly increased (4° C./min) up to 500° C., and following an additional 30 min at 500° C., it was slowly decreased to room temperature (as the oven was cooled). A glassy, dense alumina coating with the thickness of about 1 μm, completely covering the metallic wires, was obtained.

In the next step, a DSSC was fabricated from the FTO substrate with the electrochemically deposited wires. For that purpose, nanocrystalline TiO₂ layer was deposited on the aforesaid substrate by EPD, followed by mechanical pressing, as disclosed in International Publication No. WO 2007/015250 of the same applicant, herewith incorporated by reference in its entirety as if fully described herein. In particular, 1 g of commercially available titania nanopowder P-90 (Degussa AG, Germany) was mixed with 150 ml ethanol and 0.6 ml acetylacetone, and stirred with magnetic stirrer for 24 h in a closed vessel (herein “P-90 suspension”). 30 mg iodine, 6 ml acetone and 3 ml deionized water were added to 100 ml ethanol and stirred with magnetic stirrer or sonicated with cooling of the solution in an ice bath till iodine was dissolved (herein “charging solution”). After that, the P-90 suspension was added to the charging solution and mixed, followed by sonication during 15 min using an Ultrasonic Processor VCX-750 (Sonics and Materials, Inc.) to homogenize the mixture with cooling of the suspension in an ice bath. About 250 ml suspension was obtained and applied for EPD.

The electrophoretic cell contained the FTO substrate with the electrochemically deposited wires as the cathode and another piece of untreated FTO glass (8 Ohm/square) as the anode. The FTO substrate with the wires was electrically connected via the collector stripe. The two electrodes were placed vertically at a distance of 40 mm and immersed in the aforesaid suspension. The EPD process was performed at room temperature using constant current mode. A Keithley 2400 Source Meter was applied as a power supply. The current density was 0.45 mA/cm² and the deposition time was 3 min and 20 sec. At that point, after every 40 sec of deposition, the cathode was removed from the suspension and dried first at room temperature and then in an oven at a temperature of 70-120° C. for 1-3 min; cooled till room temperature; and placed again in the suspension for continued EPD. A homogeneous adherent TiO₂ nanoporous layer with thickness of 24-25 μm was obtained.

After drying at 150° C. during 40 min and cooling to room temperature, the fabricated electrode was placed on a plate of hydraulic programmable press. Hexane was uniformly dropped on the surface of the TiO₂ film, and the wet layer was immediately covered with polyethylene foil (20 μm). A pressure of 700 kg/cm² was applied, resulting in a homogeneously pressed TiO₂ film without visible defects. The thickness of the pressed titania film was 14 μm.

After sintering at 550° C. during 90 min, the fabricated electrode was applied as a photoelectrode in a DSSC. The nanoporous TiO₂ layer was sensitized with N3-dye [cis-di(isothiocyanato)-bis(4,4-dicarboxy-2,2-bipyridine) ruthenium(II)] (Dyesol, Australia) by immersing the still warm (80-100° C.) film in said dye solution (0.5 mM in ethanol) and keeping it during 72 h at room temperature. The dye-covered electrode was then rinsed with ethanol and dried under a filtered air stream. The current collector stripe was cleaned from an oxide layer by scratching. A two-electrode sandwich cell with an effective area of 9 cm² was employed to measure the performance of a DSSC using a Pt-coated FTO layered glass as a counter-electrode. The composition of the electrolyte was: 0.6 M dimethylpropylimidazolium iodide, 0.1 M LiI, 0.05 M I₂, 0.5 M 1-methyl benzimidazole in 1:1 (v/v) acetonitrile-methoxypropionitrile. Photocurrent-voltage characteristics were performed at the real sun. The illumination was 73 mW/cm². The measurement showed: short-circuit photocurrent (J_{sc}) of 11.5 mA/cm², open-circuit photovoltage (V_{oc}) 715 mV, fill factor (FF) 59.1% and light-to-electricity conversion efficiency of 6.6%. The calculation was done based on the total illuminated area, but the active area was only 85% from the total illuminated area. The light-to-electricity conversion efficiency calculated for the active area was 7.76%.

Measuring the photovoltaic performance of a DSSC prepared in the same way, but without wires, with the same illumination area of 9 cm² showed: short-circuit photocurrent (J_{sc}) of 10 mA/cm², open-circuit photovoltage (V_{oc}) 776 mV, fill factor (FF) 28.6% and light-to-electricity conversion efficiency of only 3%. These results show that the wires fabrication led to substantial improvement of both the fill factor and the photovoltaic efficiency.

### Example 2

### Electrochemical Fabrication of Nickel-Cobalt Wires on ITO/PET Conductive Plastic and DSSC Prepared Therefrom

Conductive plastic ITO coated polyester (PET), ITO/PET, with a size of 62.5 mm×40 mm (55 Ohm/square, Bekaert Specialty Films, USA) was thoroughly cleaned with ethanol, washed with water and distilled water, and dried in a filtered air stream. The ITO/PET was then covered with a mask prepared from a chemical resistant paint (Enplate Stop-Off No 1, Enthone-OMI, Inc., which is represented in Israel by Amza Surface Finishing Technologies), leaving uncovered areas for 4 wires, each area having dimensions of 40 mm×1.5 mm, with a space of 7 mm between, and an area for a collector stripe at one short side of the substrate with a length of 30 mm and a width of 3 mm at a distance of 5 mm from the edge of the substrate.

After drying of the mask at room temperature for about 1 h, electrochemical reduction of the upper layer of the ITO/PET was performed by treating the ITO/PET with a solution of 0.25 g SnCl₂.2H₂O and 10 ml distilled water in 240 ml ethanol, under stirring with magnetic stirrer at room temperature, at the cathode polarity with an inert anode (Pt anode was used). The constant current density was 2.5 mA/cm² and the duration was 20 sec. The color of the uncovered area of the ITO/PET changed from colorless to light brown due to the indium and/or tin reduction. During this treatment, tin (II) ions adsorb onto the surface and hydrolyze during following washing with distilled water. The hydrolysis products adsorb onto the reduced ITO/PET surface, which then becomes hydrophilic and, as a result, the adhesion of the metallic ions to the surface in the next step of the electrochemical or electroless deposition is improved.

For electrochemical deposition of a nickel-cobalt alloy, an electrolyte containing NiSO₄.6H₂O 30 g/l, CoSO₄.7H₂O 6 g/l, (NH₄)₂SO₄ 10 g/l and MgSO₄.7H₂O 10 g/l, with pH=6 was prepared. The deposition was carried out at room temperature, under constant current density of 5 mA/cm² for 20 min with a nickel anode. The chemical composition of the alloy was 25.8% Co and 74.2% Ni, and the height of the wires above the ITO/PET surface was 1.6 μm.

After washing and drying the substrate, the passivation of the alloy was carried out in a solution of K₂Cr₂O₇ 20 g/l at room temperature for 10 min. Then, a thin dielectric Al₂O₃-coating was deposited as described in Example 1 hereinabove; however, the deposition duration was 2 min instead of 3 min. After drying the ITO/PET substrate at ambient conditions, the masking paint was mechanically removed and the ITO/PET substrate was washed with ethanol and dried, first at ambient conditions and then at 120° C. for 30 min.

In the next step, a DSSC was fabricated from the ITO/PET substrate with the electrochemically deposited wires. For that purpose, nanocrystalline TiO₂ layer was deposited on the aforesaid substrate by EPD, followed by mechanical pressing, as described in Example 1 hereinabove. In particular, 0.65 g of commercially available titania nanopowder P-25 (Degussa AG, Germany) was mixed with 150 ml ethanol and 0.4 ml acetylacetone, and stirred with magnetic stirrer for 24 h in a closed vessel (herein “P-25 suspension”). 27 mg iodine, 4 ml acetone and 2 ml deionized water were added to 100 ml ethanol and stirred with magnetic stirrer or sonicated with cooling of the solution in an ice bath till iodine was dissolved (herein “charging solution”). After that, the P-25 suspension was added to the charging solution and mixed, followed by sonication during 15 min using an Ultrasonic Processor VCX-750 (Sonics and Materials, Inc.) to homogenize the mixture with cooling of the suspension in an ice bath. About 250 ml suspension was obtained and applied for EPD.

The electrophoretic cell contained the ITO/PET substrate with the electrochemically deposited wires as the cathode and FTO conductive glass (8 Ohm/square) as the counter-electrode. The ITO/PET substrate with the wires was electrically connected via the collector stripe. The two electrodes were placed vertically at a distance of 30 mm and immersed in the aforesaid suspension. The EPD process was performed at room temperature using constant current mode. A Keithley 2400 Source Meter was applied as a power supply. The current density was 0.33 mA/cm² and the deposition time was 2 min. A homogeneous adherent TiO₂ nanoporous layer with thickness of 12-14 μm was obtained.

After drying at 90° C. during 40 min and cooling to room temperature, the fabricated electrode was placed on a plate of hydraulic programmable press. Hexane was uniformly dropped on the surface of the TiO₂ film, and the wet layer was immediately covered with polyethylene foil (20 μm). A pressure of 800 kg/cm² was applied, resulting in a homogeneously pressed TiO₂ film without visible defects. The thickness of the pressed titania film was 7-7.5 μm.

In order to further improve the photovoltaic performance of the DSSC fabricated from this electrode, a titania polymeric coating was deposited by a sol-gel EPD process, as described in Example 1 hereinabove (for alumina coating). For that purpose, 15 mg iodine, 4 ml acetone and 2 ml deionized water were added to 250 ml ethanol, and the mixture was stirred with magnetic stirrer for 24 h in a closed vessel. Using an inert atmosphere glove box, 0.2 ml of Ti(OiC₃H₇)₄ was placed in a bottle and hermetically sealed. The sealed bottle was transferred outside the glove-box, where under ambient conditions the above-mentioned solution was added to the precursor, inside the bottle, under vigorous stirring. The solution was stirred during 24 h resulting in ˜250 ml transparent sol (the color of the sol gradually changed from yellow to colorless). The sol was left for aging in a closed vessel without stirring at ambient conditions for 7 days, after which it was ready for EPD. The resulting transparent sol was applied for sol-gel EPD coating of titania nanoporous electrode on the ITO/PET with the wires. The electrophoretic cell contained two electrodes placed vertically at a distance of 40 mm in the aforesaid transparent sol. The titania nanoporous electrode on the ITO/PET with the wires served as the cathode and a FTO conductive glass served as a counter-electrode. The EPD process was performed at room temperature under constant current, using a Keithley 2400 Source Meter as a power supply. The current density was 80 μA/cm² and the EPD duration was 2 min. After drying the coated electrode, first at ambient conditions and then in an oven at 150° C. for 40 min, the fabricated electrode was applied as photoelectrode in a DSSC.

The photovoltaic measurement was carried out as described in Example 1 hereinabove. The nanoporous TiO₂ layer was sensitized with N3-dye (Dyesol, Australia) by immersing the still warm (80-100° C.) film in said dye solution (0.5 mM in ethanol) and keeping it during 72 h at room temperature. The dye-covered electrode was then rinsed with ethanol and dried under a filtered air stream.

A two-electrode sandwich cell with an effective area of 9 cm² was employed to measure the performance of a DSSC using a Pt-coated FTO layered glass as a counter-electrode. The composition of the electrolyte was: 0.6 M dimethylpropylimidazolium iodide, 0.1 M LiI, 0.05 M I₂, 0.5 M 1-methyl benzimidazole in 1:1 (v/v) acetonitrile-methoxypropionitrile. Photocurrent-voltage characteristics were performed at the real sun. The illumination was 80 mW/cm². The illumination area was 9 cm². The measurement showed: short-circuit photocurrent (J_{sc}) of 4.5 mA/cm², open-circuit photovoltage (V_{oc}) 776 mV, fill factor (FF) 60.5% and light-to-electricity conversion efficiency of 2.6%. Measuring the photovoltaic performance of a DSSC prepared in the same way, but without wires, with the same illumination area of 9 cm², showed: short-circuit photocurrent (J_{sc}) of 1.2 mA/cm², open-circuit photovoltage (V_{oc}) 745 mV, fill factor (FF) 24.6% and light-to-electricity conversion efficiency of only 0.27%. These results show that the wires fabrication led to substantial improvement of both the fill factor and the photovoltaic efficiency.

### Example 3

### Electrochemical Fabrication of Ag Layer on ITO-Glass

ITO-glass, with a size of 7 mm×50 mm×0.7 mm (8-12 Ohm/square, Delta Technologies, USA) was thoroughly cleaned with acetone, ethanol, and mild soap, washed with water and distilled water, and dried in a filtered air stream. Reduction of the upper layer of the ITO was then performed in an electrochemical cell by treating the ITO-glass with an electrolyte of NH₄Cl (1 g/l) in distilled water at room temperature, at the cathode polarity with an inert anode (Pt wire was used). The constant current density was 10 mA/cm² and the duration was 12 sec. The color of the ITO-glass changed from colorless to light brown due to the indium and tin reduction.

After washing with distilled water, still wet, the sample was used for electrochemical deposition of silver. A similar sample of reduced ITO-glass after washing with distilled water was dried in a filtered air stream and analyzed by HRSEM and FIB. FIGS. 17-18, presenting HRSEM images of the initial and reduced ITO-glass, show that the reduction of the ITO surface results in spherical and/or oval nanoparticles of the reduced indium and tin and also nano-size holes. FIG. 18B, presenting 45°-tilted HRSEM image of the reduced sample, shows that the nanoparticles of the reduced metal leave the upper ITO surface and are positioned on top of the ITO surface, and the holes are formed in the upper ITO surface from where the metal left. It is obvious that the surface roughness is increased due to the reduction.

The silver deposition on the nanostructured ITO obtained following the reduction process described above was performed in three steps, from three electrolytes having different compositions. Since silver is a relatively noble metal, it is expected to form immersion deposits on the surfaces of less noble metal such as indium and tin reduced from the ITO. This tends to happen even when less noble metal enters the silver electrolyte with a voltage already applied, and the inevitable result of this phenomenon is poor adhesion of subsequent deposits. In order to minimize this effect, a silver strike process was first employed, using a composition of KAg(CN)₂ (2.4 g/l); KCN (90 g/l); and NaNO₃ (400 g/l).

The Ag strike electrodeposition was performed in an electrochemical cell,

wherein the nanostructured ITO-glass was connected to the cathode polarity, and Pt anode was applied. The nanostructured ITO-glass was immersed into the electrolyte under voltage already applied. The cathode current density was 9.3 mA/cm² and the duration of the deposition was 1 min. After short rinsing in water by dipping, this sample was applied in the second silver deposition step, using a composition of AgNO₃ (12.5 g/l); KCN (28 g/l); NaNO₃ (180 g/l); NH₄NO₃ (0.5 g/l); and KNO₃ (100 g/l).

The second Ag electrodeposition step was performed in an electrochemical cell, wherein the sample after the first Ag electrodeposition step was connected to the cathode polarity, and Ag anode was applied. The sample was immersed into the electrolyte without voltage applied. The cathode current density was 9.3 mA/cm² and the duration of the deposition was 1 min Then, without rinsing, this sample was applied in the third silver deposition step, using a composition of AgNO₃ (25 g/l); KCN (28 g/l); NaNO₃ (100 g/l); NH₄NO₃ (0.5 g/l; and KNO₃ (100 g/l).

The third Ag electrodeposition step was performed in an electrochemical cell, wherein the sample after the second Ag electrodeposition step was connected to the cathode polarity, and Ag anode was applied. The sample was immersed into the electrolyte without voltage applied. The cathode current density was 9.3 mA/cm² and the duration of the deposition was 1.5 min. After rinsing with water and distilled water, and drying by a filtered air stream, an adhesion test was performed using an adhesive tape. The adhesion of the electrodeposited silver to the ITO was excellent, as evidenced by the fact that not even a small part of the silver was removed from the ITO-glass. The thickness and the morphology of the deposited Ag layer were controlled by FIB and HRSEM. FIGS. 20A-20B, presenting top-view HRSEM image of silver deposited on nanostructured ITO-glass (20A), and FIB image of a cross-section thereof (20B), show that the silver layer is dense with a thickness of about 880 nm, and is well attached to the ITO due to silver penetration into the nano-holes of the nanostructured ITO, and good adhesion between the nanoparticles of the reduced metal and the silver. Due to the high conductivity of Ag and the dense metallic structure, the electrodeposited silver layer has very good electrical conductivity. The roughness of the deposited silver layer was still high due to the absence of additives, but after addition of grain refiners or brighteners, this layer can become lustrous or fully bright.

In order to investigate how the silver electrodeposition starts, HRSEM images of a nanostructured sample of ITO-glass after the first step of silver deposition, i.e., after Ag strike, were obtained, and a 45°-tilted HRSEM image is shown in FIG. 21. A comparison between FIG. 21 and FIG. 18B, showing a 45°-tilted HRSEM image of the reduced ITO-glass, indicates that at the beginning of the electrochemical deposition, silver is preferably deposited on nanoparticles of the reduced metal (indium and tin), and consequently, the shape of those nanoparticles is changed from spherical and/or oval to irregular, and the size of the metallic nanoparticles is increased.

### Example 4

### Electrochemical Fabrication of Cu Layer on ITO-Glass

The nano-structuring of the upper surface of ITO-glass similar to that used in Example 3 was performed by a process similar to that described in Example 3, except for that the reduction of the ITO was performed with an electrolyte of NH₄Cl (0.75 g/l) in distilled water, using a current density of 7.4 mA/cm² during 8 sec. The copper deposition on the nanostructured ITO obtained following the reduction process was performed in one step from an electrolyte having a composition of: CuSO₄.5H₂O (30 g/l); (NH₄)₂SO₄ (100 g/l); NH₄NO₃ (60 g/l); and NH₄OH (25%) (180 g/l), and a pH in the range of 8.5-9.

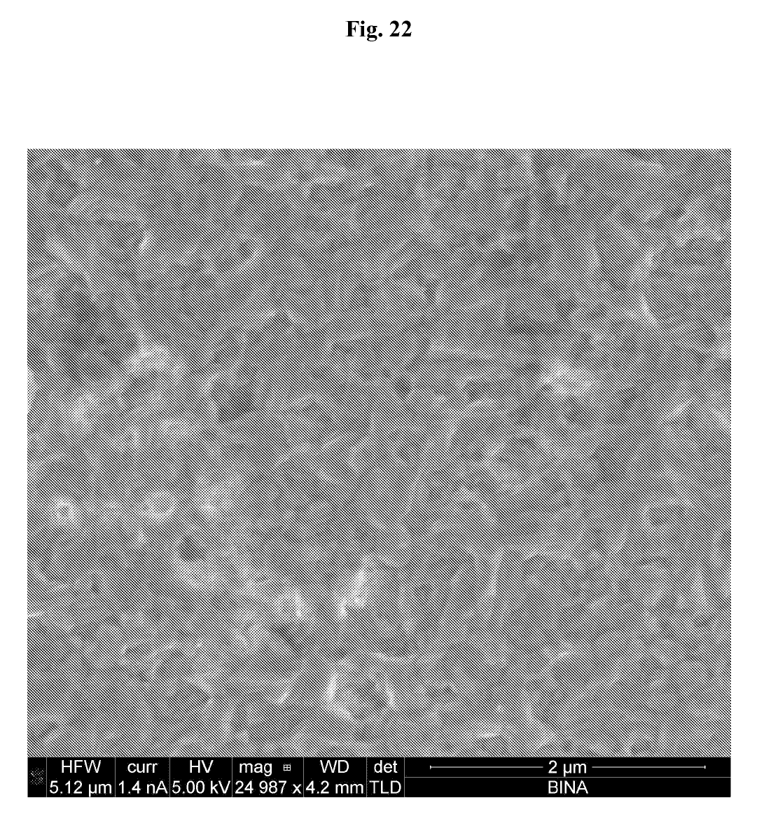

The copper electrodeposition was performed in an electrochemical cell at room temperature. The ITO-glass was connected to the cathode polarity, and Cu anode was used. The nanostructured ITO-glass was immersed in the electrolyte under voltage already applied. The cathode current density was 30 mA/cm² and the duration of the deposition was 6.5 min. After rinsing with water and distilled water, and drying by a filtered air stream, an adhesion test using an adhesive tape was performed. This test showed that the adhesion of the electrodeposited copper to the ITO was excellent, as evidenced by the fact that not even a small part of the copper was removed from the ITO-glass. The thickness and the morphology of the deposited Cu layer were controlled by FIB and HRSEM. FIGS. 22-23, presenting a top-view HRSEM image of the Cu deposited on the ITO-glass and a FIB image of a cross-section thereof, respectively, show that the copper layer is dense with a thickness of about 1.7 micron, and is very well attached to the ITO. The surface roughness of the copper layer was low, and the copper layer looked lustrous.

### Example 5

### Electrochemical Fabrication of Cu Layer on FTO-Glass

FTO-glass with a size of 5.6 cm×1.25 cm (15 Ohm/square, Pilkington, USA) was thoroughly cleaned with trichloroethylene, ethanol and mild soap, washed with water and distilled water, and dried in a filtered air stream. Reduction of the upper layer of the FTO was then performed in an electrochemical cell by treating the FTO-glass with an electrolyte of NH₄Cl (1.5 g/l) in distilled water at room temperature, at the cathode polarity with an inert anode (Pt wire was used). The constant current density was 10 mA/cm² and the duration was 40 sec. The color of the FTO-glass changed from colorless to light brown due to the tin reduction.

Etching of the reduced tin was then performed in a solution of 80 ml/l of concentrated HCl in distilled water till the sample became once again colorless (about 1.5 min) After careful washing with water and distilled water, still wet, the sample was used for electrochemical deposition of copper. Similar samples of reduced FTO-glass and etched FTO-glass were dried in a filtered air stream and were then analyzed by HRSEM and FIB. FIGS. 1-3 show top-view and 45°-tilted HRSEM images of FTO-glass 15 Ohm/square prior to nano-structuring, after reduction, and after reduction and etching of the metal nanoparticles, respectively; and FIB images of cross-sections of said FTO prior to and after nano-structuring are shown in FIGS. 4-5, respectively. As clearly observed from these images, the reduction of the FTO surface results in the creation of nano-size holes and grooves in said surface, and spherical and/or oval tin nanoparticles on said surface. As further observed, the etching of the reduced tin results in removal of tin nanoparticles, although the roughness of the FTO surface following the etching is yet remarkably higher than that of the FTO surface prior to the nano-structuring process.

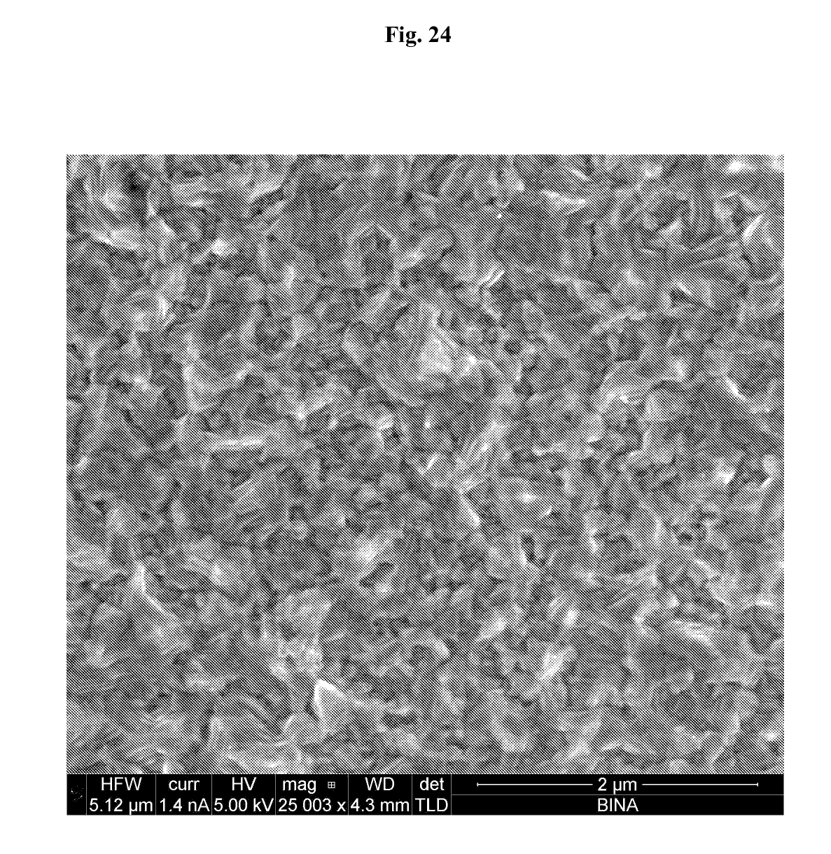

The copper deposition on the nanostructured FTO-glass obtained following the reduction and etching processes was performed in a process similar to that described in Example 4; however, the duration of the copper electrodeposition was 10 min. An adhesion test using an adhesive tape showed that the adhesion of the electrodeposited copper to the FTO was excellent, as evidenced by the fact that not even a small part of the copper was removed from the FTO-glass. The thickness and the morphology of the deposited Cu layer were controlled by FIB and HRSEM. FIGS. 24-25, presenting a top-view HRSEM image of the Cu layer deposited on the FTO-glass and a FIB image of a cross-section thereof, respectively, show that the copper layer is dense with a thickness of about 2.18 micron, and it is very well attached to the FTO due to very good penetration of the copper into the nano-holes and nano-grooves of the nanostructured FTO surface. The roughness of the copper surface was low, and the deposited copper layer looked bright.

### Example 6

### Nano-Structures on TCO Coated Substrates after Selective Etching of the Deposited Metal

In order to evaluate whether a product consisting of a TCO on which a metal or metal alloy is electrochemically or chemically deposited was prepared according to the process described herein, metals deposited on preliminarily nanostructured TCO samples were removed by etching, trying to observe “finger-prints”.

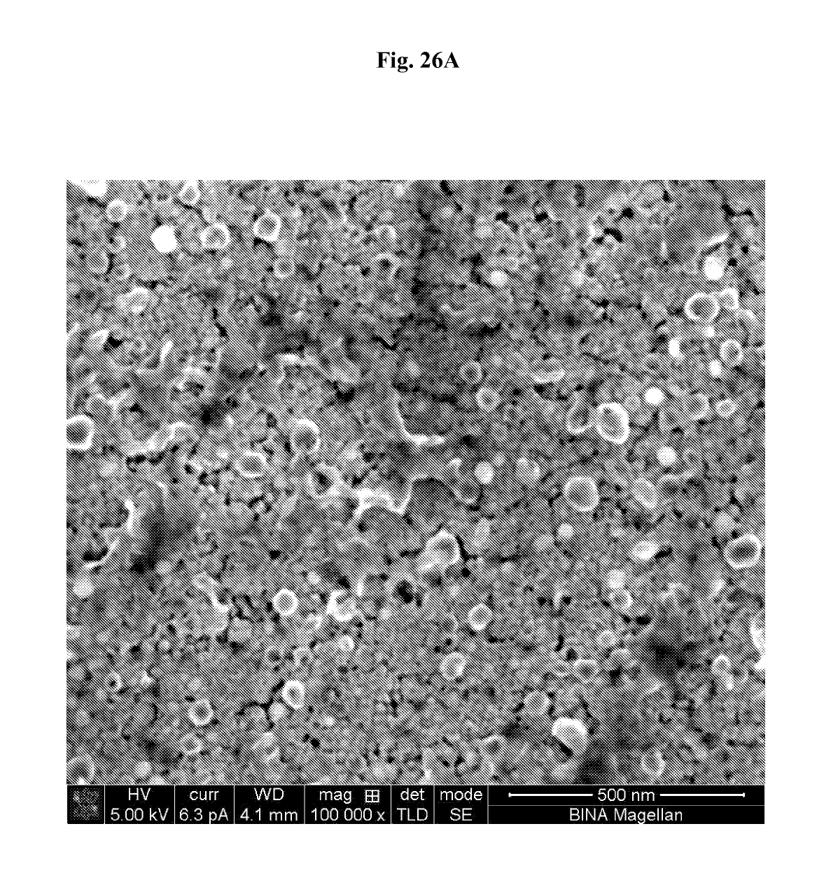

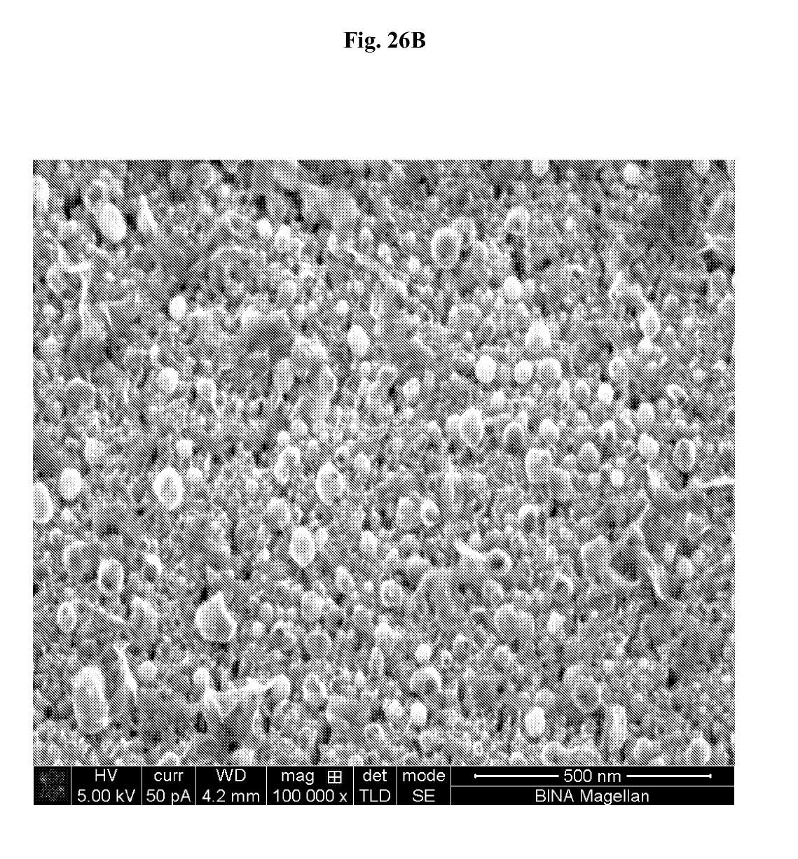

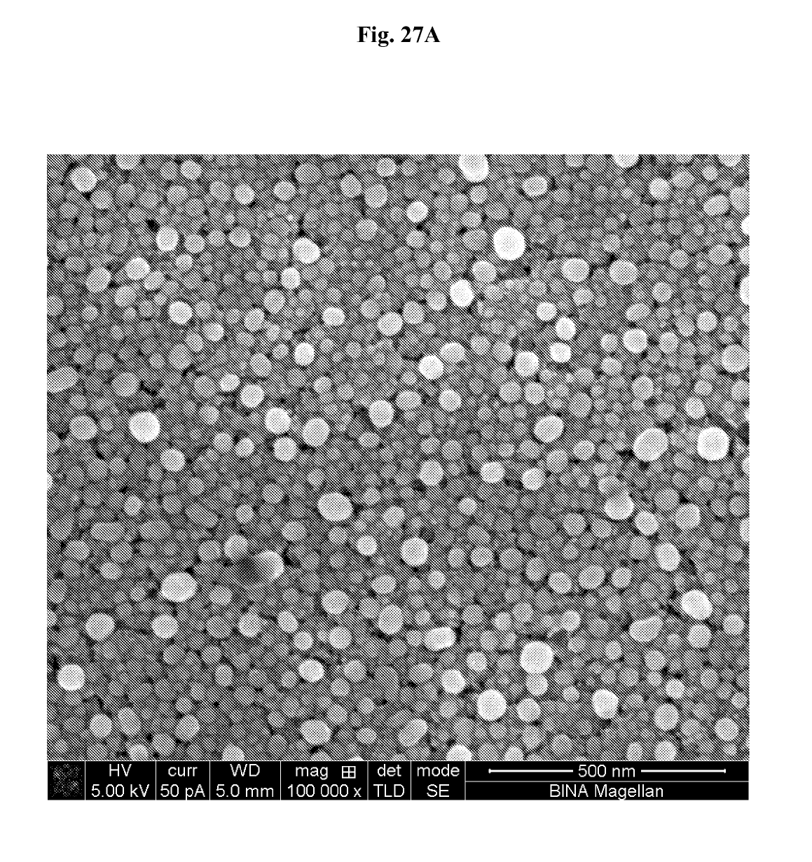

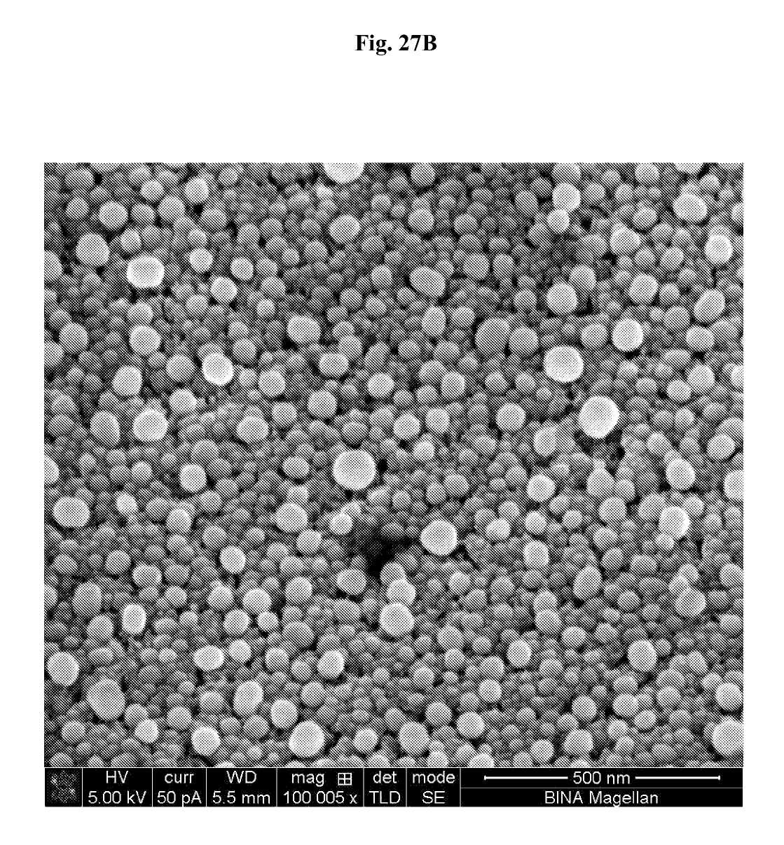

In particular, etching of electrodeposited Ag or Cu from preliminarily nanostructured ITO-glass prepared as described in Examples 3 and 4, respectively, was performed in a solution of 0.5 M NaI and 0.05 M I₂ in propylene carbonate, until the deposited metal was almost completely removed from the nanostructured ITO-glass. After careful rinsing in water and distilled water, and drying in a filtered air stream, the surfaces of the samples obtained were analyzed by HRSEM. FIG. 26 shows top-view and 45°-tilted HRSEM images of the nanostructured ITO-glass surface after etching of a deposited silver layer, and FIG. 27 shows top-view and 45°-tilted HRSEM images of the nanostructured ITO-glass surface after etching of a deposited copper layer. As shown in these Figures, the patterns obtained by nano-structuring of the ITO-glass prior to the silver or copper electrodeposition remained almost intact, except for that (i) the indium and tin nanoparticles resulting from the reduction of indium and tin ions in the upper layer of the ITO surface and observed following the nano-structuring process and prior to the metal deposition, became smaller and their shape from round and/or oval became distorted round and/or oval due to the etching process in the iodine-iodide solution (especially in the case of silver etching); and (ii) the size of the nano-holes became bigger, apparently due to the same reason. In the case of silver etching, some non-identified remnants are visible, as shown in FIG. 26.

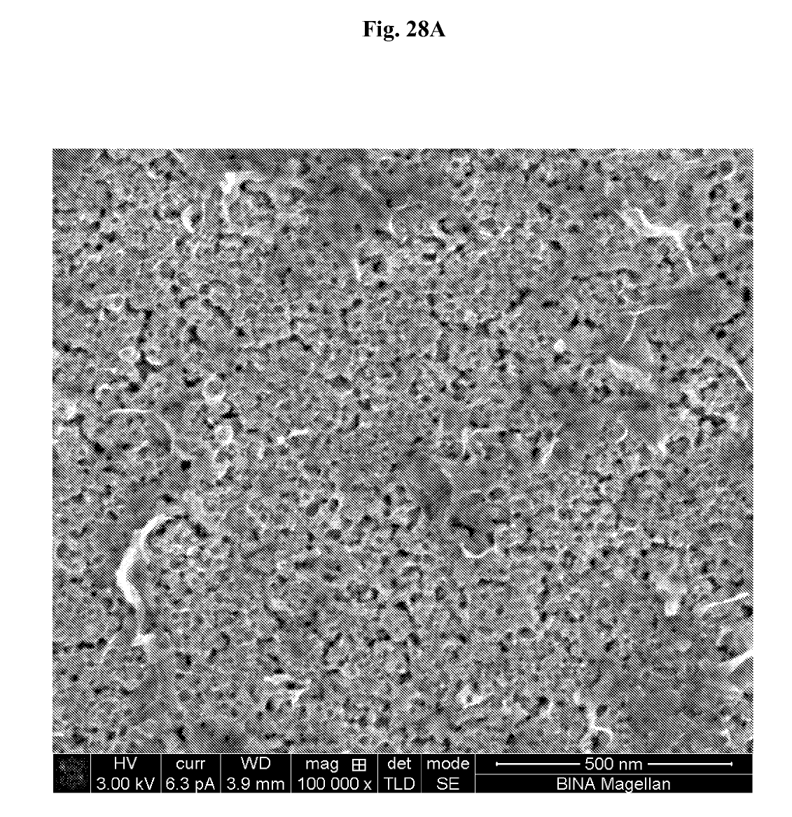

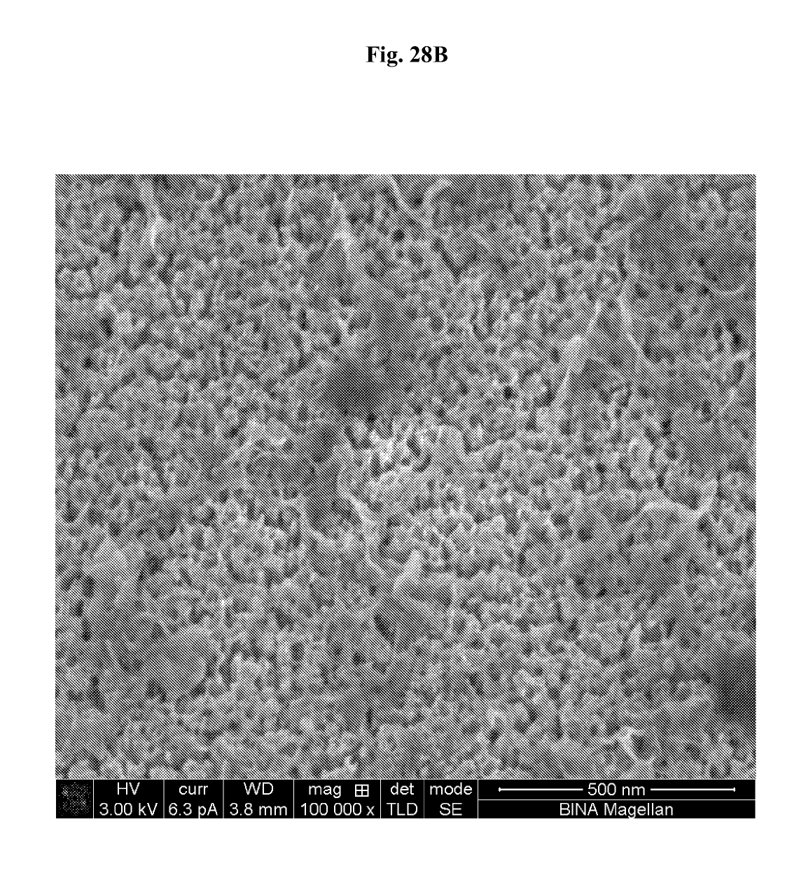

Etching of the deposited silver in the same solution for a longer time period resulted in almost complete removal of the indium and tin nanoparticles obtained during the reduction of ITO, and even bigger nano-holes forming also chains of nano-holes, as shown in FIG. 28. Nevertheless, non-identified remnants as shown in FIG. 26 were visible in this case as well.

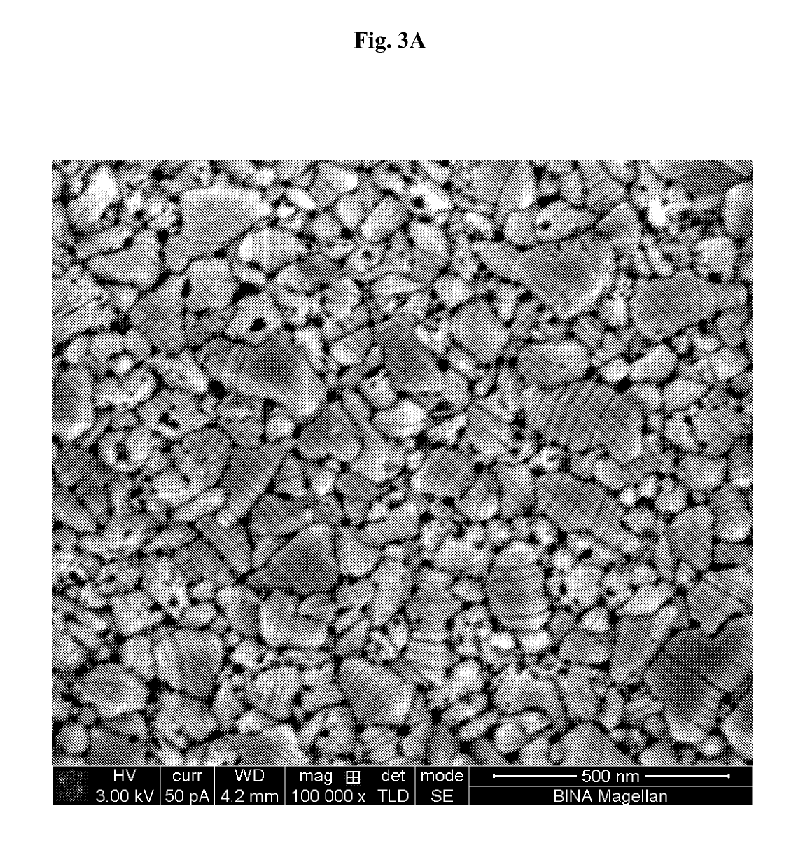

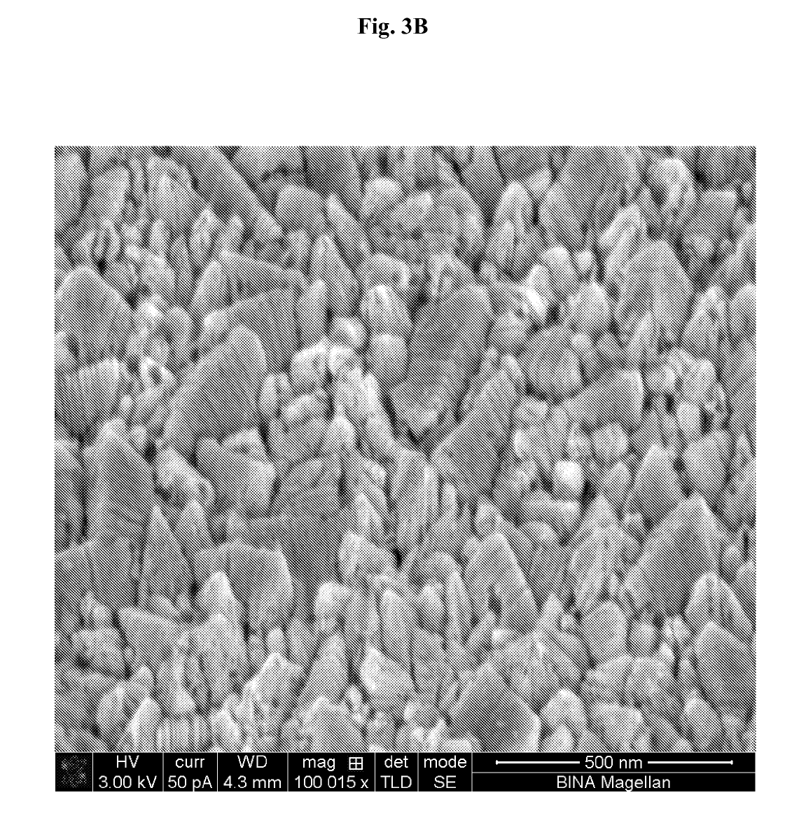

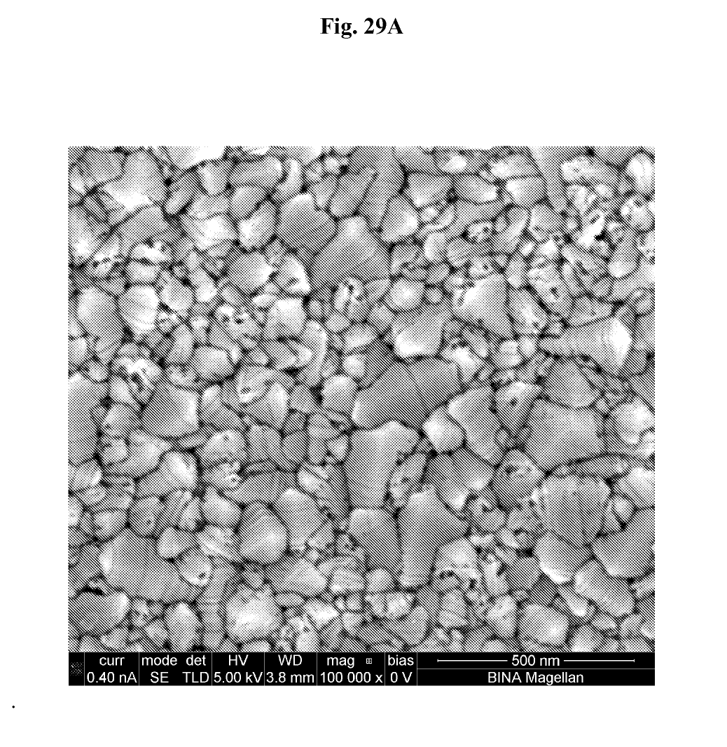

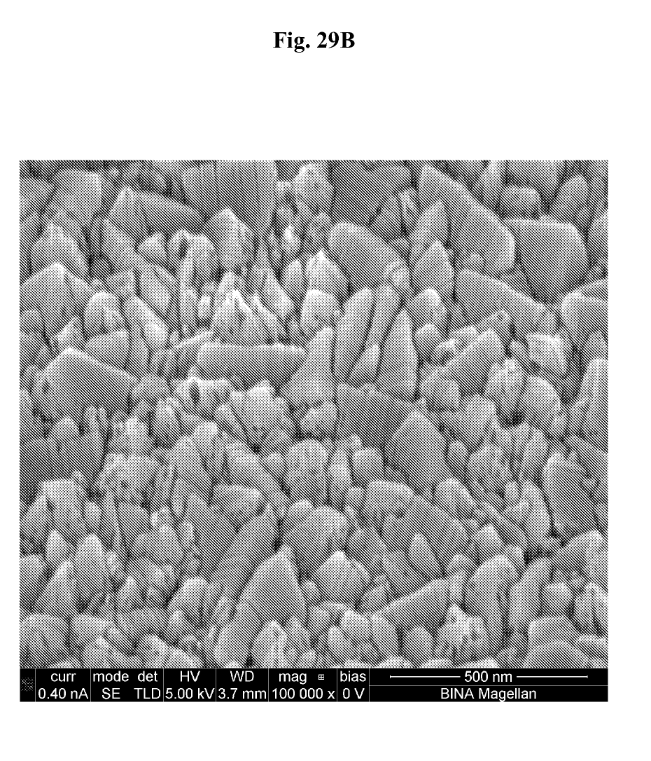

Furthermore, in particular, etching of electrodeposited copper from preliminarily nanostructured FTO-glass prepared as described in Example 5 was performed in a solution (NH₄)₂S₂O₈ 240 g/l and HgCl₂ 0.027 g/l until the deposited copper was almost completely removed from the nanostructured FTO-glass. After careful rinsing in water and distilled water, and drying in a filtered air stream, the surface of the obtained sample was analyzed by HRSEM. FIG. 29 shows top-view and 45°-tilted HRSEM images of the nanostructured FTO-glass surface after etching of a deposited copper layer. As shown in these images, the pattern obtained by etching of the electrodeposited copper from a preliminary nanostructured FTO-glass remained the same as the pattern obtained by the nano-structuring of the FTO-glass before the copper electrodeposition (see FIG. 3) due to the remarkably higher chemical stability of FTO compared with that of ITO.

### REFERENCES

Arakawa, H. et al., Book of abstracts of 16^{th} international conference on photochemical conversion and storage of solar energy, Uppsala, Sweden, Jul. 2-7, 2006, W4-P-10
Dai, S. Wang, K. Weng, J. Sui, Y. Huang, Y. Xiao, S. Chen, S. Hu, L. Kong, F. Pan, X. Shi, C. Guo, L., Sol. Energy Mater. Sol. Cells, 2005, 85, 447-455
Grätzel, M., Prog. Photovolt: Res. Appl., 2000, 8, 171-185
Grätzel, M., Prog. Photovolt: Res. Appl., 2006, 14, 429-442
Kay, A. Grätzel, M., Sol. Energy Mater. Sol. Cells, 1996, 44, 99-117
Späth, M. Sommeling, P. M. van Roosmalen, J. A. M. Smit, H. J. P. van der Burg, N. P. G. Mahieu, D. R. Bakker, N. J. Kroon, J. M., Prog. Photovolt: Res. Appl., 2003, 11, 207-220
Tulloch, G. E., J. Photochem. Photobiol. A: Chem., 2004, 164, 209-219

1. A transparent conductive oxide (TCO) comprising a metal oxide either doped with ions of a chemical element or in a slightly reduced form, wherein said TCO has a nanostructured upper surface being characterized by (i) nano-holes, nano-grooves, nano-nets and/or chains of nano-holes; and optionally (ii) nanoparticles and/or nano-islands of a metal reduced from metal ions in said TCO.

2. The TCO of claim 1, wherein said nanostructured upper surface obtained by a method comprising reduction of metal ions in the upper layer of a surface of a TCO; and optionally etching of the reduced metal nanoparticles and/or nano-islands obtained.

3. The TCO of claim 1, wherein said TCO is fluorine-doped tin oxide (FTO), tin-doped indium oxide (ITO), antimony-doped tin oxide, aluminum-doped zinc oxide, gallium-doped zinc oxide, indium-doped zinc oxide, zinc oxide in a slightly reduced form, aluminum-doped cadmium oxide, gallium-doped cadmium oxide, or indium-doped cadmium oxide.

4. The TCO of claim 1, wherein each one of said metal nanoparticles have a spherical, oval, distorted spherical, or distorted oval shape; and each one of said metal nano-islands have an irregular shape.

5. The TCO of claim 2, wherein the reduction of said metal ions is carried out by reducing plasma, a chemical process, or an electrochemical process.

6. The TCO of claim 5, wherein the reduction of said metal ions is carried out by an electrochemical process.

7. The TCO of claim 5, wherein said electrochemical reduction is carried out in an electrochemical cell, wherein the TCO is connected to the cathode polarity; the anode is made of an inert insoluble conductive material; and the electrolyte is a diluted solution of at least one salt in water and/or in a polar organic solvent.

8. The TCO of claim 7, wherein the anode is made of graphite, platinum, a TCO, or titanium coated with platinum.

9. The TCO of claim 7, wherein the electrolyte is a diluted solution of at least one salt in water supplemented with a polar organic solvent, or a diluted solution of at least one salt in a polar organic solvent supplemented with water.

10. The TCO of claim 7, wherein each one of said at least one salt independently consists of an anion selected from the group consisting of halide, nitrate, perchlorate and sulphate, and a cation selected from the group consisting of ammonium, sodium, potassium, aluminum, and magnesium.

11. The TCO of claim 7, wherein said polar organic solvent is a linear or branched C₁-C₆ alkanol such as methanol, ethanol, propanol, iso-propanol, butanol, isobutanol, sec-butanol, tert-butanol, pentanol, neopentanol, sec-pentanol, and hexanol, acetylacetone, glycerin, ethyleneglycol, propylene carbonate, or a mixture thereof.

12. The TCO of claim 7, wherein said electrochemical reduction is carried out in two or more steps using a different electrolyte in each step.

13. The TCO of claim 2, wherein the etching of said reduced metal nanoparticles and/or nano-islands is carried out in an aqueous and/or polar organic solvent solution selected from the group consisting of an acid or a base solution, a complexing agent solution, a solution of an oxidizing agent together with a complexing agent, and a solution of an oxidizing agent together with an acid or a base.

14. The TCO of claim 13, wherein said polar organic solvent is a linear or branched C₁-C₄ alkanol such as methanol, ethanol, propanol, iso-propanol, butanol, sec-butanol, and tert-butanol, acetylacetone, acetonitrile, glycerin, ethyleneglycol, propylene carbonate, or a mixture thereof.

15. The TCO of claim 13, wherein said acid solution is a solution of hydrochloric acid, nitric acid, sulphuric acid, acetic acid, oxalic acid, citric acid, sulfamic acid, or a mixture thereof; said base solution is a solution of sodium hydroxide, potassium hydroxide, ammonium hydroxide, tetramethylammonium hydroxide, tetraethylammonium hydroxide, tetrapropylammonium hydroxide, or tetrabutylammonium hydroxide; said oxidizing agent is iodine, chlorine, bromine, hydrogen peroxide, FeCl₃, CuCl₂, K₂Cr₂O₇, KMnO₄, NaClO, (NH₄)₂O₉, or Ce(NH₄)₂(NO₃)₆; and said complexing agent is ammonium chloride, ammonium bromide, ammonium iodide, ammonium citrate, ammonium hydroxide, sodium citrate, potassium-sodium tartrate, Trilon B, potassium cyanide, or sodium cyanide.

16. The TCO of claim 13, wherein the etching of said reduced metal nanoparticles and/or nano-islands is carried out in two or more steps, using a different solution in each step.

17. The TCO of claim 1, further comprising, on said nanostructured upper surface, a layer of a metal or an alloy thereof.

18. The TCO of claim 17, obtained by electrochemical or electroless deposition of said metal or alloy on said nanostructured upper surface.

19. The TCO of claim 18, wherein said metal is Ag, Cu, Au, Ni, Co, Fe, Pd, Pt, Sn, Pb, Zn, Cd, Ga, In, Tl, Ge, Sb, or Bi.

20. The TCO of claim 19, wherein said alloy is silver-antimony alloy, silver-nickel alloy, silver-palladium alloy, silver-cadmium alloy, silver-lead alloy, silver-indium alloy, silver-cobalt alloy, silver-copper alloy, silver-gold alloy, silver-platinum alloy, silver-bismuth alloy, copper-zinc alloy, nickel-copper alloy, copper-tin alloy, copper-zinc-tin alloy, copper-lead alloy, copper-indium alloy, gold-copper alloy, gold-silver alloy, gold-nickel alloy, gold-cobalt alloy, gold-silver-copper alloy, gold-antimony alloy, gold-indium alloy, nickel-cobalt alloy, nickel-iron alloy, nickel-chromium-iron alloy, nickel-palladium alloy, nickel-tungsten alloy, nickel-tin alloy, nickel-molybdenum alloy, nickel-cobalt-rhenium alloy, nickel-ruthenium alloy, nickel-chromium alloy, nickel-indium alloy, nickel-cobalt-indium alloy, cobalt-indium alloy, or cobalt-tungsten alloy.

21. An optoelectronic device comprising a TCO according to claim 17.

22. An organic light-emitting diode (OLED) device according to claim 21.

23. The OLED device of claim 22, wherein said metal or alloy layer is deposited on said nanostructured upper surface according to a pattern of a metallic busbar (grid) structure to thereby increase the conductivity of a substrate on which said TCO is deposited and uniformly spread the current over said substrate to ensure homogeneous emission.

24. A photovoltaic cell comprising a TCO according to claim 17.

25. The photovoltaic cell of claim 24, selected from an organic thin film (OPV) solar cell, a compound semiconductor thin film solar cell, or a dye sensitized solar cell (DSSC).

26. The photovoltaic cell of claim 25, wherein said metal or alloy is deposited on said nanostructured upper surface according to a pattern of a metallic current-collecting grid to thereby increase the conductivity of a substrate on which said TCO is deposited and reduce resistive losses.

27. A photochemical water splitting device comprising a TCO according to claim 17.

28. The photochemical water splitting device of claim 27, wherein said metal or alloy is deposited on said nanostructured upper surface according to a pattern of a metallic current-distributing and/or current-collecting grid to thereby increase the conductivity of a substrate on which said TCO is deposited and reduce resistive losses.
